(19) United States
(12) Patent Application Publication
(10) Pub. No.: US 2025/0323143 A1
(43) Pub. Date: Oct. 16, 2025

(54) SEMICONDUCTOR STRUCTURE

(71) Applicant: Taiwan Semiconductor Manufacturing Company, Ltd., Hsinchu (TW)

(72) Inventor: Jhon-Jhy LIAW, Zhudong Township (TW)

(21) Appl. No.: 18/631,274

(22) Filed: Apr. 10, 2024

(51) Int. Cl. H01L 23/522; H01L 23/528; H01L 29/06; H01L 29/423; H01L 29/786

(52) U.S. Cl. CPC H01L 23/5226; H01L 23/5286; H10D 30/6735; H10D 30/6757; H10D 62/121; H10D 62/127

(57) ABSTRACT

A semiconductor structure is provided. The semiconductor structure includes a first circuit in a first cell region, a first contact plug, a first metal layer and a second metal layer. The first circuit includes a first n-type nanostructure transistor and a first p-type nanostructure transistor. The first contact plug is electrically connected to drain nodes of the first n-type nanostructure transistor and the first p-type nanostructure transistor. The first metal layer is over the first contact plug, and includes a first line and a second line electrically connected to the first contact plug. The second metal layer is over the first metal layer, and includes a third line electrically connected to both the first line and the second line.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2A is a top view of a standard (STD) cell array, in accordance with some embodiments of the disclosure.

FIG. 2B is a layout (top view) illustrating a semiconductor structure including a first cell region and a second cell region in a standard cell array, in accordance with some embodiments of the disclosure.

FIG. 2C illustrates the configuration between drain-node contact plugs in a first cell region and a second cell region and a second metal layer, in accordance with some embodiments of the disclosure.

FIG. 3 is a layout (top view) illustrating a semiconductor structure including a first cell region and a second cell region in a standard cell array, in accordance with some embodiments of the disclosure.

FIG. 4A is a top view of two standard cell arrays, in accordance with some embodiments of the disclosure.

FIG. 4B is a layout (top view) illustrating a semiconductor structure including a first cell region and a second cell region in respective standard cell arrays, in accordance with some embodiments of the disclosure.

FIGS. 5A-1, 5B-1, 5C-1 and 5D-1 are cross-sectional views illustrating the formation of a semiconductor structure, in accordance with some embodiments of the disclosure.

FIGS. 5A-2, 5B-2, 5C-2 and 5D-2 are cross-sectional views illustrating the formation of a semiconductor structure, in accordance with some embodiments of the disclosure.

FIGS. 5A-3, 5B-3, 5C-3 and 5D-3 are cross-sectional views illustrating the formation of a semiconductor structure, in accordance with some embodiments of the disclosure.

FIG. 6A illustrates the configuration between a drain-node contact plug in a second cell region and a second metal layer, in accordance with some embodiments of the disclosure.

FIG. 6B illustrates the configuration between a drain-node contact plug in a second cell region and a second metal layer, in accordance with some embodiments of the disclosure.

FIG. 6C illustrates the configuration between a drain-node contact plug in a second cell region and a second metal layer, in accordance with some embodiments of the disclosure.

FIGS. 7-1 and 7-2 are cross-sectional views of a semiconductor structure, in accordance with some embodiments of the disclosure.

FIG. 8 is a cross-sectional view of a semiconductor structure, in accordance with some embodiments of the disclosure.

FIG. 9A is a top view of a standard cell array, in accordance with some embodiments of the disclosure.

FIG. 9B is a layout (top view) illustrating a semiconductor structure including a first cell region and a second cell region in a standard cell array, in accordance with some embodiments of the disclosure.

FIGS. 10-1, 10-2 and 10-3 are cross-sectional views of a semiconductor structure, in accordance with some embodiments of the disclosure.

FIG. 11A illustrates the configuration between a contact plug and a second metal layer of a second cell region, in accordance with some embodiments of the disclosure.

FIG. 11B illustrates the configuration between a contact plug and a second metal layer of a second cell region, in accordance with some embodiments of the disclosure.

FIG. 11C illustrates the configuration between a contact plug and a second metal layer of a second cell region, in accordance with some embodiments of the disclosure.

FIG. 12A is a top view of a standard cell array, in accordance with some embodiments of the disclosure.

FIG. 12B is a layout (top view) illustrating a semiconductor structure including a first cell region and a second cell region in a standard cell array, in accordance with some embodiments of the disclosure.

FIGS. 13-1, 13-2 and 13-3 are cross-sectional views of a semiconductor structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

A single chip may embed multiple circuits (or CMOSFETs) with different electrical connection structures to serve high-density and high-speed applications. For example, circuits with larger channel widths may be used for high-speed circuits, while circuits with smaller channel widths may be used for high-density circuits and enable high component density.

Embodiments of a semiconductor structure are provided. The semiconductor structure includes a high-density circuit in the first cell region and a high-speed circuit in the second cell region. The high-speed circuit includes a drain-node contact plug that is electrically connected in parallel to a line of the second-level metal layer (M2), thereby reducing the IR voltage drop. The high-density circuit includes a drain-node contact plug that is electrically connected in series to a line of the second-level metal layer (M2), thereby increasing connection density. Therefore, more design freedom and co-optimization of component density and device performance of the resulting semiconductor device may be achieved.

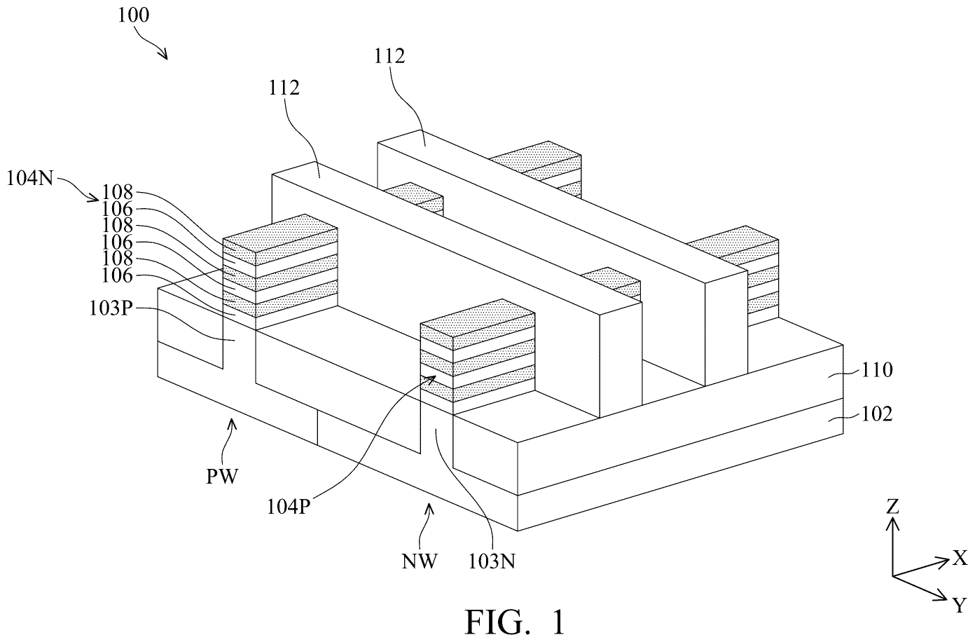

FIG. 1 is a perspective view of a semiconductor structure 100, in accordance with some embodiments of the disclosure.

The semiconductor structure 100 includes a substrate 102 and fin structures 104 (including 103N and 103P) over the substrate 102, as shown in FIG. 1, in accordance with some embodiments. The substrate 102 includes a p-type well PW and an n-type well NW immediately adjacent to the p-type well PW, in accordance with some embodiments. The fin structure 104N is formed in the p-type well PW of the substrate 102, and the fin structure 104P is formed in the n-type well NW of the substrate 102, in accordance with some embodiments. The fin structures 104N and 104P are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104N includes a lower fin element 103P formed from the p-type well PW, and the fin structure 104P includes a lower fin element 103N formed from the n-type well NW, in accordance with some embodiments. The lower fin elements 103P and 103N are surrounded by an isolation structure 110, in accordance with some embodiments. Each of the fin structures 104N and 104P further includes an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104N and 104P extend in the X direction, in accordance with some embodiments. That is, the fin structures 104N and 104P have longitudinal axes parallel to the X direction, in accordance with some embodiments. The X direction may also be referred to as the channel direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same.

Gate structures 112 are formed with longitudinal axes parallel to the Y direction and extending across and/or surrounding the channel regions of the fin structures 104N and 104P, in accordance with some embodiments. The source/drain regions of the fin structures 104N and 104P are exposed from the gate structures 112, in accordance with some embodiments. The Y direction may also be referred to as a gate-routing direction.

Although two fin structures 104 are illustrated in FIG. 1, the semiconductor structure 100 may include more than two fin structures 104. In addition, FIG. 1 shows two gate structures 112 (or channel regions) for illustrative purposes and is not intended to be limiting. The number of fin structures and the gate structures may be dependent on the design demand of an integrated circuit and/or performance consideration of semiconductor devices.

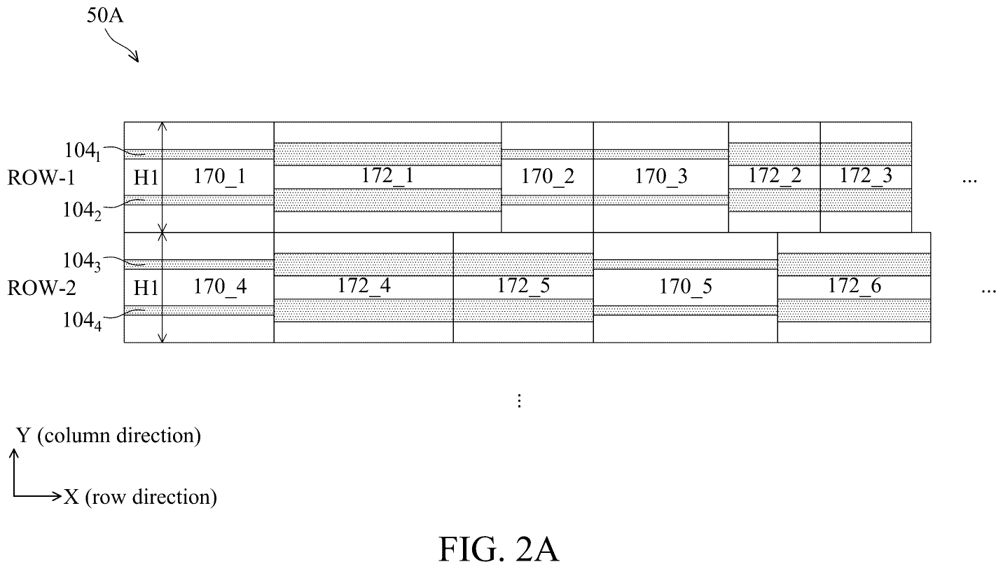

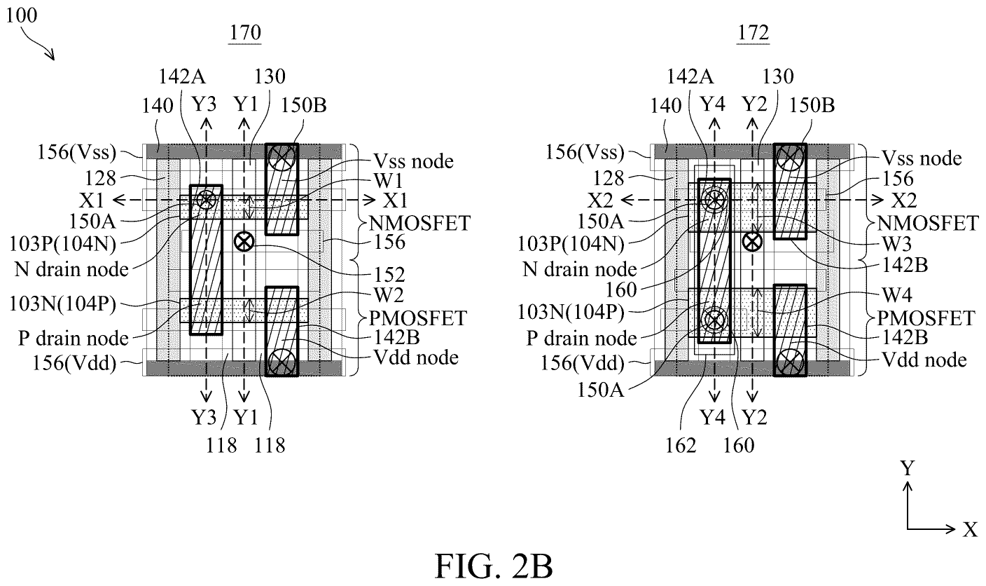

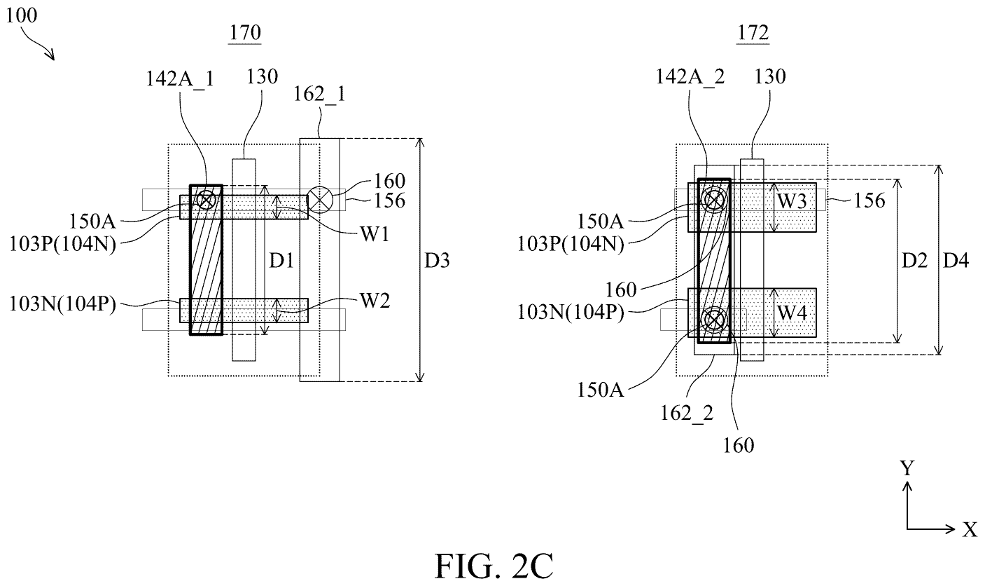

FIG. 2A is a top view of a standard (STD) cell array 50A, in accordance with some embodiments of the disclosure.

The standard cell array 50A includes a plurality of first cell regions 170 and a plurality of second cell regions 172 arranged in rows and in columns, as shown in FIG. 2A, in accordance with some embodiments. The cell regions 170 and 172 may have rectangular shapes in the top view, and the edges (or boundaries) of the cell regions 170 and 172 extend in the X direction (row direction) and the Y direction (column direction), in accordance with some embodiments. The first cell regions 170 and the second cell regions 172 are standard cells, and have the same cell height H1, in accordance with some embodiments.

Each of the first cell regions 170 and the second cell regions 172 includes a functional circuit, e.g., a logic circuit such as inverter, NAND gate, NOR gate, flip-flops, SCAN, or another suitable circuit. The first cell regions 170 include high-density circuits, and the second cell regions include high-current circuits, in accordance with some embodiments. The circuit in the cell regions 170 and 172 may be interconnected with each other to form an integrated circuit, in accordance with some embodiments. In some embodiments, the high-current circuits in the cell array 50A may have a good area utilization of the substrate.

The circuits of the first cell regions 170 and the second cell regions 172 each include multiple transistors which are formed from active regions 104 and gate stacks (not shown in FIG. 2A), in accordance with some embodiments. The active regions 104 may be the fin structures 104 in FIG. 1. The active regions 104 continuously extend in the X direction (row direction) through multiple cell regions 170 and 172, in accordance with some embodiments. The active regions 104 may be referred to as continuous oxide definition (CNOD). For example, in some embodiments, the active regions 1041 and 1042 pass through the cell regions 170_1, 172_1, 170_2, 170_3, 172_2 and 172_3 arranged in the row ROW-1. The active regions 1043 and 1044 pass through the cell regions 170_4, 172_4, 172_5, 170_5, 172_6 arranged in the row ROW-2.

The active regions 104 are semiconductor strips with a jog structure, in accordance with some embodiments. As the term is used herein, “jog” refers to a strip extending in a horizontal direction, with a dent or protrusion on one or both sides of the strip. The active region 104 with a jog structure may include narrower portions and wider portions, in accordance with some embodiments. The narrower portions of the active regions 104 are used to form the high-density circuits in the first cell regions 170, and the wider portions of the active regions 104 are used to form the high-speed circuits in the second cell regions 172, as shown in FIG. 2A, in accordance with some embodiments.

FIG. 2B is a layout (top view) illustrating a semiconductor structure 100 including a first cell region 170 and a second cell region 172 in the standard cell array 50A of FIG. 2A, in accordance with some embodiments of the disclosure.

The semiconductor structure 100 includes active regions 104 (including 104N and 104P), gate stacks 130, fin-cut structures 128, gate-cut structures 140, contact plugs 142A and 142B, first-level vias 150A, 150B and 152, a first-level metal layer (M1), second-level vias 160 and a second-level metal layer (M2), as shown in FIG. 2B, in accordance with some embodiments of the disclosure. These components of the semiconductor structure 100 function as interconnected functional circuits, in accordance with some embodiments. Each of the functional circuits is defined in one cell region (e.g., 170 or 172), in accordance with some embodiments. FIG. 2B illustrates a first cell region 170 and a second cell region 172 separate from each other, for example, by one or more cell region(s) 170 or 172. In some embodiments, the first cell region 170 and the second cell region 172 have the same cell height H1.

The active regions 104N and 104P are formed over a substrate (as shown in FIG. 1) and extend in the X direction, in accordance with some embodiments. In some embodiments where the cell regions 170 and 172 of FIG. 2B are arranged in the same row, the active regions 104N and 104P may continuously extend through the cell region 170 and 172 of FIG. 2B. The substrate includes a p-type well and an n-type well (not shown in FIG. 2B), in accordance with some embodiments. The p-type well and the n-type well are immediately arranged in the Y direction, in accordance with some embodiments. The active regions 104N are located on the p-type well, and the active regions 104P are located on the n-type well, in accordance with some embodiments.

In some embodiments, in the Y direction, the active region 104N in the first cell region 170 (including a high-density circuit) has a channel width W1 and the active region 104N in the second cell region 172 (including a high-speed circuit) has a channel width W3. In some embodiments, the channel width W3 is greater than the channel width W1. In some embodiments, the ratio (W3/W1) of the channel width W3 to the channel width W1 is in a range from about 1.5 to about 8, for example, about 1.5 to about 2.

In some embodiments, in the Y direction, the active region 104P in the first cell region 170 has a channel width W2 and the active region 104P in the second cell region 172 has a channel width W4. In some embodiments, the channel width W4 is greater than the channel width W2. In some embodiments, the ratio (W4/W2) of the channel width W4 to the channel width W2 is in a range from about 1.5 to about 8, for example, about 1.5 to about 2. In some embodiments, the ratio (W3/W1) is equal to the ratio (W4/W2). In some other embodiments, the ratio (W3/W1) may be not equal to the ratio (W4/W2).

Each of the active regions 104 includes a lower fin element 103N (or 103P) and nanostructures (not shown in FIG. 2B) formed over the lower element 103N (or 103P), in accordance with some embodiments. The gate stacks 130 extend in the Y direction and across the lower fin elements 103N and 103P, and wrap around the nanostructures of the active regions 104N and 104P, in accordance with some embodiments. Gate spacer layers 118 are formed along the opposite sides of the gate stacks 130, in accordance with some embodiments.

The gate stacks 130 are combined with the active regions 104 to form nanostructure transistors, in accordance with some embodiments. The nanostructure transistors are formed at the cross points between the active regions 104 and the gate stacks 130, in accordance with some embodiments. The nanostructure transistors which are formed on the active regions 104N in the p-type well are n-channel nanostructure transistors NMOSFET, and the nanostructure transistors which are formed on the active regions 104P in the n-type well are p-channel nanostructure transistors PMOSFET, in accordance with some embodiments.

The fin-cut structures 128 extend in the Y direction and cut through the active regions 104N and 104P, in accordance with some embodiments. In some embodiments, the fin-cut structures 128 are formed by replacing the gate structures with dielectric material. The gate spacer layers 118 are also formed along the opposite sides of the fin-cut structures 128, in accordance with some embodiments. The gate-cut structures 140 extend in the X direction and cut through the gate stack 130, the fin-cut structures 128 and the gate spacer layers 118, in accordance with some embodiments.

The gate-cut structures 140 and the fin-cut structures 128 may be configured to collectively define boundaries of the cell regions 170 or 172. For example, the gate-cut structures 140 correspond to the boundaries of the cell regions 170 or 172 with respect to the Y direction (extending in the X direction), and the fin-cut structures 128 correspond to the boundaries of cell regions 170 or 172 with respect to the X direction (extending in the Y direction), in accordance with some embodiments.

The contact plugs 142 (including 142A and 142B) are formed on the source/drain regions of the active regions 104N and 104P, in accordance with some embodiments. The contact plugs 142 have longitudinal extending in the Y direction, in accordance with some embodiments. In each of the cell regions 170 and 172, one contact plug 142A is electrically connected to the drain nodes (or terminals) of both the n-channel nanostructure transistor NMOSFET and the p-channel nanostructure transistor PMOSFET, in accordance with some embodiments. In each of the cell regions 170 and 172, two contact plugs 142B are electrically connected to the respective source nodes (or terminals) of the n-channel nanostructure transistor NMOSFET the p-channel nanostructure transistor PMOSFET, in accordance with some embodiments.

The first-level metal layer (M1) is formed over the contact plugs 142A and 142B and includes several conductive lines (tracks) 156, e.g., power supply lines and signal lines, in accordance with some embodiments. The first-level metal layer is electrically connected to the contact plugs 142A through first-level vias 150A, to the contact plugs 142B through first-level vias 150B, and to the gate stack 130 through first-level vias 152, in accordance with some embodiments. The first-level vias 150A/B may also be referred to as source/drain vias (VS or VD), and the first-level vias 152 may also be referred to as gate vias (VG), in accordance with some embodiments.

The power supply lines include a Vdd power rail providing positive voltage and a Vss power rail which may be an electrical ground, in accordance with some embodiments. The Vss power rail 156 is electrically connected to the Vss node (e.g., source terminals) of the n-channel nanostructure transistors, in accordance with some embodiments. The Vdd 156 power rail is electrically connected to the Vdd node (e.g., source terminals) of the p-channel nanostructure transistors, in accordance with some embodiments. The signal lines are configured for signal transmission and are electrically isolated from the power supply lines, in accordance with some embodiments.

The lines 156 of the first-level metal layer M1 extend in the X direction, in accordance with some embodiments. The Vdd and Vss power rails 156 extend along and overlap the boundaries of the cell regions 170 and 172 with respect to the Y direction, in accordance with some embodiments. In some embodiments where the cell region 170 and 172 of FIG. 2B are arranged in the same row, the Vdd and Vss power rails 156 may continuously extend through the cell regions 170 and 172. The signal lines 156 are located between the power supply lines, in accordance with some embodiments. The signal lines 156 are electrically connected to the gate stacks 130 and the drain nodes of the n-channel transistors and p-channel transistors, in accordance with some embodiments.

The second-level metal layer (M2) is formed over the first-level metal layer (M1), and electrically connected to the first-level metal layer (M1) through second-level vias 160, in accordance with some embodiments. Although FIG. 2B only shows one line 162 of the second-level metal layer in the second cell region 172, the second-level metal layer may include several conductive lines (tracks) 162 extending in the Y direction, in accordance with some embodiments. In the second cell region 172, the drain-node contact plug 142A is electrically connected in parallel to a line 162 of the second-level metal layer (M2) through two second-level vias 160, two lines 156 of the first-level metal layer (M1) and two first-level vias 150A, in accordance with some embodiments.

As the scale of the semiconductor devices continues to shrink, the scaling of metal layers in BEOL has been touched by the limitation on both resistance and capacitance due to increasingly smaller line width and line space. The performance improvement (e.g., increase in speed) of semiconductor devices (e.g., logic circuits) cannot rely solely on the device boosting, but also needs to concern about the IR voltage drop. The high-speed circuits having wider channel widths (e.g., W3 and W4) may have higher on-state current than the high-density circuits having narrower channel widths (e.g., W1 and W2), and thus the high-speed circuits have higher on-state current (e.g., Idsat) and may suffer a greater IR voltage drop.

The embodiments of the present disclosure may provide two parallel connection paths (e.g., contact plug 142A and line 162) for the drain node of the CMOSFET of the high-speed circuits with larger channel width to reduce IR voltage drop, and provide one longer contact connection path (e.g., contact plug 142A) for the drain node of the CMOSFET of the high-density circuits with smaller channel width to save metal routing layers for increased connection density. Therefore, it may provide more design freedom and co-optimization of component density and device performance.

FIG. 2C illustrates the configuration between drain-node contact plugs 142A in the first cell region 170 and the second cell region 172 and lines 162 of a second-level metal layer M2, in accordance with some embodiments of the disclosure.

In the first cell region 170, the drain-node contact plug 142A_1 is electrically connected in series to a line 162_1 of the second-level metal layer (M2) through a second-level via 160, a line 156 of the first-level metal layer (M1) and a first-level via 150A, as shown in FIG. 2C, in accordance with some embodiments. The line 162_1 of the second-level metal layer (M2) may not overlap the drain-node contact plug 142A_1, in accordance with some embodiments. The second-level via 160 may not overlap the first-level via 150A, in accordance with some embodiments. The line 162_1 may extend beyond the boundaries of the first cell region 170, and include a portion outside the area of the first cell region 170, or alternatively, the line 162_1 may be entirely outside the area of the first cell region 170, in accordance with some embodiments.

In the second cell region 172, the drain-node contact plug 142A_2 and a line 162_2 of the second-level metal layer M2 are electrically connected in parallel, in accordance with some embodiments. That is, the connection of the contact plug 142A_2 and the line 162_2 uses at least two sets of second-level via 160, line 156 and first-level via 150A (e.g., three sets, four sets, etc.). The line 162_2 of the second-level metal layer (M2) overlaps the drain-node contact plug 142A_2, in accordance with some embodiments. The contact plug 142A_2 is entirely located within the area of the line 162_2, in accordance with some embodiments. In some other embodiments, the contact plug 142A_2 may have a portion inside the area of the line 162_2 and another portion outside the area of the line 162_2. The second-level vias 160 overlap the first-level vias 150A, in accordance with some embodiments.

In some embodiments, in the Y direction, the dimension (length) D1 of the contact plug 142A_1 is less than the dimension (length) D2 of the contact plug 142A_2. In some embodiments, in the Y direction, the dimension (length) D3 of the line 162_1 is greater than the dimension (length) D4 of the line 162_2. In some embodiments, dimension D3 of the line 162_1 is greater than the dimension D1 of the contact plug 142A_1. In some embodiments, the dimension D4 of the line 162_2 is greater than the dimension D2 of the contact plug 142A_2. In some other embodiments, the dimension D4 of the line 162_2 may be less than the dimension D2 of the contact plug 142A_2.

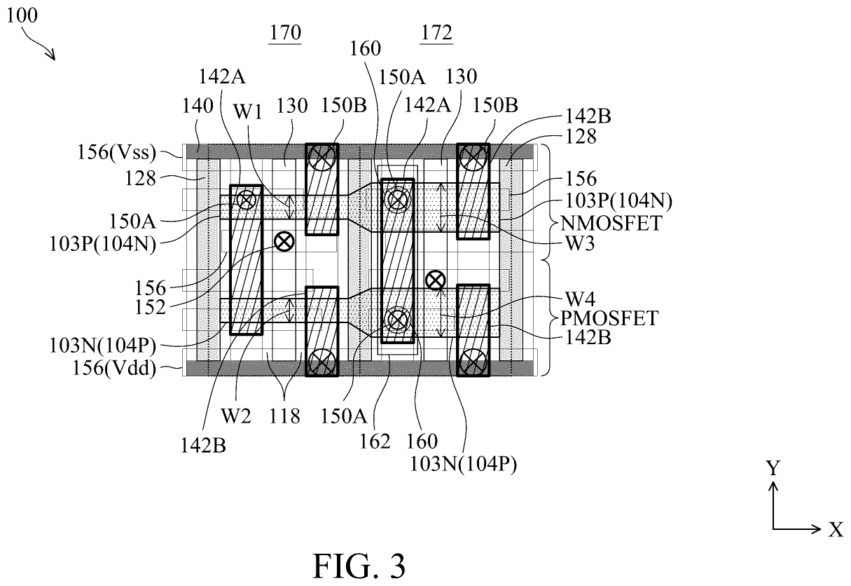

FIG. 3 is a layout (top view) illustrating a semiconductor structure 100 including a first cell region 170 and a second cell region 172 in the standard cell array 50A of FIG. 2A, in accordance with some embodiments of the disclosure. The embodiments of the FIG. 3 are similar to the embodiments of FIG. 2B except that the first cell region 170 abuts and/or is immediately adjacent to the second cell region 172. In some embodiments where the channel width ratio (i.e., W3/W1 and W4/W2) is small, one fin-cut structure 128 corresponds to and is located at the boundary between the first cell region 170 and the second cell region 172 to electrically isolate the first cell region 170 and the second cell region 172.

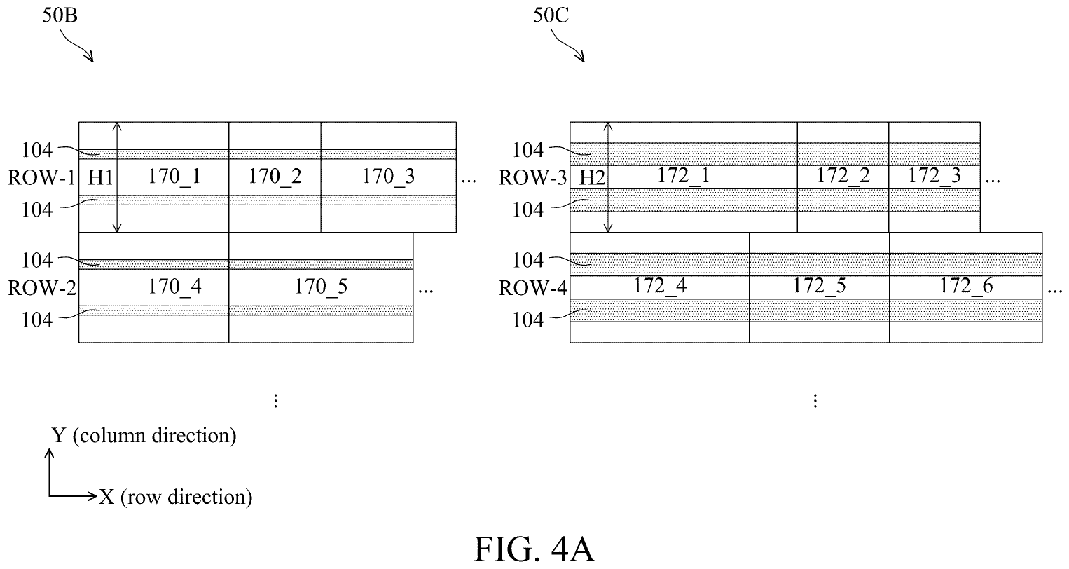

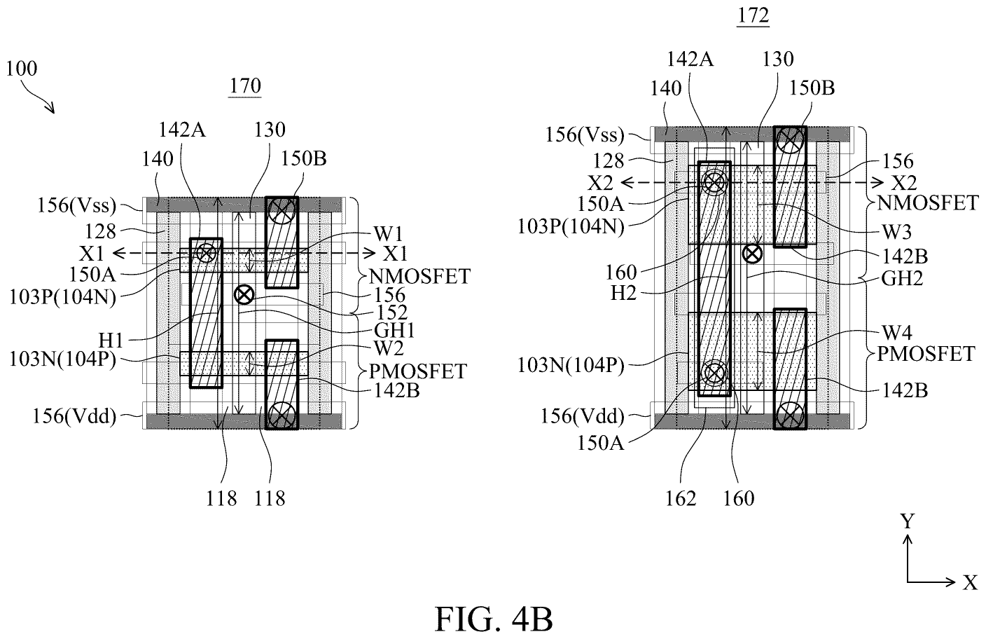

FIG. 4A is a top view of two standard cell arrays 50B and 50C, in accordance with some embodiments of the disclosure. FIG. 4B is a layout (top view) illustrating a semiconductor structure 100 including a first cell region 170 and a second cell region 172 in the respective standard cell arrays 50B and 50C of FIG. 4A, in accordance with some embodiments of the disclosure.

The standard cell array 50A includes a plurality of first cell regions 170 arranged in rows ROW-1 and ROW-2, and the standard cell array 50B includes a plurality of second cell regions 172 in rows ROW-3 and ROW-4, as shown in FIG. 4A, in accordance with some embodiments. The first cell regions 170 include high-density circuits, and the second cell regions 172 include high-current circuits, in accordance with some embodiments. The active region 104 forming the high-density circuits of the first cell regions 170 are narrower than the active region 104 forming the high-speed circuits of the second cell regions 172, in accordance with some embodiments.

The cell height H1 of the first cell region 170 is less than the cell height H2 of the second cell region 172, as shown in FIGS. 4A and 4B, in accordance with some embodiments. In some embodiments, the ratio (H2/H1) of the cell height H2 to the cell height H1 is in a range from about 1.1 to about 3. Due to the mismatch of the cell height H1 and the cell height H2, the first cell regions 170 and the second cell regions 172 cannot be arranged in the same cell array, in accordance with some embodiments. The length GH1 of the gate stack 130 of the first cell regions 170 is less than the length GH2 of the gate stack 130 of the second cell regions 172, as shown in FIG. 4B, in accordance with some embodiments. In some embodiments, the lengths GH1 and GH2 are in a range from about 5 nm to about 20 nm. In some embodiments, the ratio (GH2/GH1) of the length GH2 to the length GH1 is in a range from about 1.1 to about 3.

Referring back to FIG. 2B, reference cross-sections are illustrated to use in later figures. Cross-sections X1-X1 and X2-X2 are in planes parallel to the longitudinal axis (X direction) of the active region 104N and through the active regions 104N of the cell regions 170 and 172. Cross-sections Y1-Y1 and Y2-Y2 are in planes parallel to the longitudinal axis (Y direction) of the gate stack 130 and through the gate stack 130 of the cell regions 170 and 172. Cross-sections Y3-Y3 and Y4-Y4 are in planes parallel to the longitudinal axis (Y direction) of the gate stack 130 and across drain-node contact plugs 142A.

FIGS. 5A-1 through 5D-3 are cross-sectional views illustrating the formation of the semiconductor structure 100 at various intermediate stages, in accordance with some embodiments of the disclosure.

FIGS. 5A-1, 5A-2 and 5A-3 illustrate the semiconductor structure 100 after the formation of active regions 104 (including 104N and 104P), an isolation structure 110, dummy gate structures 112 (including 112₁ to 112₆) and gate spacer layers 118 respectively corresponding to line X1-X1 and line X2-X2, line Y1-Y1 and line Y2-Y2, and line Y3-Y3 and line Y4-Y4.

A semiconductor structure 100 is provided, and the semiconductor structure 100 includes a first cell region 170 and a second cell region 172 which may be the cells 170 and 172 in the cell array 50A of FIG. 2A, or in the cell arrays 50B and 50C of FIG. 4A, in accordance with some embodiments. A substrate 102 is provided, as shown in FIGS. 5A-1 to 5A-3, in accordance with some embodiments. The substrate 102 may be a portion of a semiconductor wafer, a semiconductor chip (or die), and the like. In some embodiments, the substrate 102 is a silicon substrate.

In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

N-type dopants (such as phosphorus or arsenic) may be implanted into the substrate 102, thereby forming an n-type well NW, in accordance with some embodiments. P-type dopants (such as boron or BF₂) may be implanted into the substrate 102, thereby forming a p-type well PW, in accordance with some embodiments. In some embodiments, the respective concentrations of the dopants in the wells are in a range from about 10¹⁶/cm⁻³ to about 10¹⁸/cm⁻³. In some embodiments, the ion implantation processes may be performed several times with different dosages and different energy intensities. In some embodiments, the ion implantation process may include an anti-punch through (APT) implant.

Active regions 104N (including 104N_1 and 104N2) and active regions 104P (104P_1 and 104P_2) are formed over the substrate 102, as shown in FIGS. 5A-1 to 5A-3, in accordance with some embodiments. In the first cell region 170, the active region 104N_1 is formed in the p-type well PW, and the active region 104P_1 is formed in the n-type well NW, in accordance with some embodiments. In the second cell region 172, the active region 104N_2 is formed in the p-type well PW, and the active region 104P_2 is formed in the n-type well NW, in accordance with some embodiments. In some embodiments, the active regions 104N and 104P extend in the X direction. That is, the active regions 104N and 104P have longitudinal axes parallel to the X direction, in accordance with some embodiments.

The formation of the active regions 104N and 104P includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

The formation of the active regions 104N and 104P further includes patterning the epitaxial stack and the underlying p-type and n-type wells PW and NW using photolithography and etching processes, thereby forming trenches and the active regions 104N and 104P protruding from between trenches, in accordance with some embodiments. The portion of the p-type well PW protruding from between the trenches serves as lower fin elements 103P of the active regions 104N, and the portion of the n-type wells NW protruding from between the trenches serves as lower fin elements 103N of the active regions 104P, in accordance with some embodiments. A remainder of the epitaxial stack (including the first semiconductor layers 106 and the second semiconductor layers 108) serves as the upper fin elements of the active regions 104N and 104P, in accordance with some embodiments.

In some embodiments, each of the first semiconductor layers 106 has a thickness T1 in a range from about 4 nm to about 15 nm. In some embodiments, each of the second semiconductor layers 108 has a thickness T2 in a range from about 3 nm to about 8 nm. In some embodiments, the pitch of the second semiconductor layers 108 (e.g., the sum of thicknesses T1 and T2) is in a range from about 7 nm to about 23 nm. The thickness of the second semiconductor layers 108 may be greater than, equal to, or less than the first semiconductor layers 106, depending on the amount of gate materials to be filled in spaces where the first semiconductor layers 106 are removed.

In some embodiments, the active region 104N_1 has a width W1′ and the active region 104N_2 has a channel width W3′. In some embodiments, the width W3′ is greater than the width W1′. In some embodiments, the ratio (W3′/W1′) of the channel width W3′ to the channel width W1′ is in a range from about 1.5 to about 8. In some embodiments, the active region 104P_1 has a width W2′ and the active region 104P_2 has a channel width W4′. In some embodiments, the width W4′ is greater than the width W2′. In some embodiments, the ratio (W4′/W2′) of the channel width W3′ to the channel width W1′ is in a range from about 1.5 to about 8. Although three first semiconductor layers 106 and three second semiconductor layers 108 are shown in FIGS. 5A-1 to 5A-3, the number is not limited to three, and can be two or four, and is less than 10.

An isolation structure 110 is formed to surround the lower fin elements 103P and 103N, as shown in FIGS. 5A-2 and 5A-3, in accordance with some embodiments. The isolation structure 110 is configured to electrically isolate the active regions 104 from each other and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove the portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the upper fin elements of the active regions 104 are exposed, in accordance with some embodiments.

Dummy gate structures 112 (including 112₁ to 112₆) are formed across the active regions 104N and 104P, as shown in FIGS. 5A-1 and 5A-2, in accordance with some embodiments. The gate structures 112₁ to 112₃ are formed in the first cell region 170, and the gate structures 112₄ to 112₆ are formed in the second cell region 172, in accordance with some embodiments. The dummy gate structures 112 are configured as sacrificial structures and will be replaced with the final gate stacks and the fin-cut structures, in accordance with some embodiments. In some embodiments, the dummy gate structures 112 extend in the Y direction and surround the channel regions of the active regions 104N and 104P, in accordance with some embodiments.

Each of the dummy gate structure 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed using ALD, CVD, thermal oxidation, physical vapor deposition (PVD), another suitable technique, or a combination thereof. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HfTIO, HfAlO.

In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof. Once the material for the dummy gate electrode layer 116 is deposited, the material for the dummy gate electrode layer 116 is planarized, and the material for the dummy gate electrode layer 116 and the dielectric material are patterned into the dummy gate structure 112 using photolithography and etching processes.

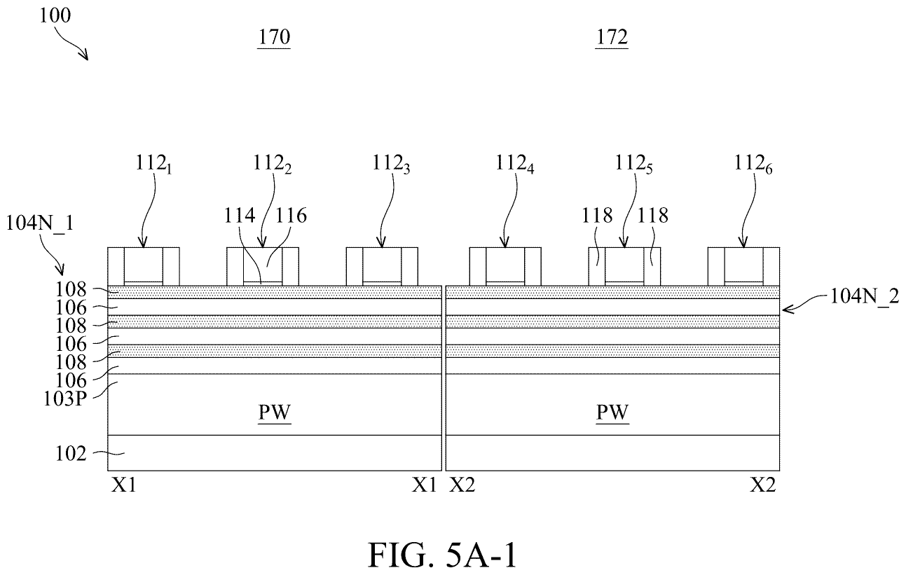

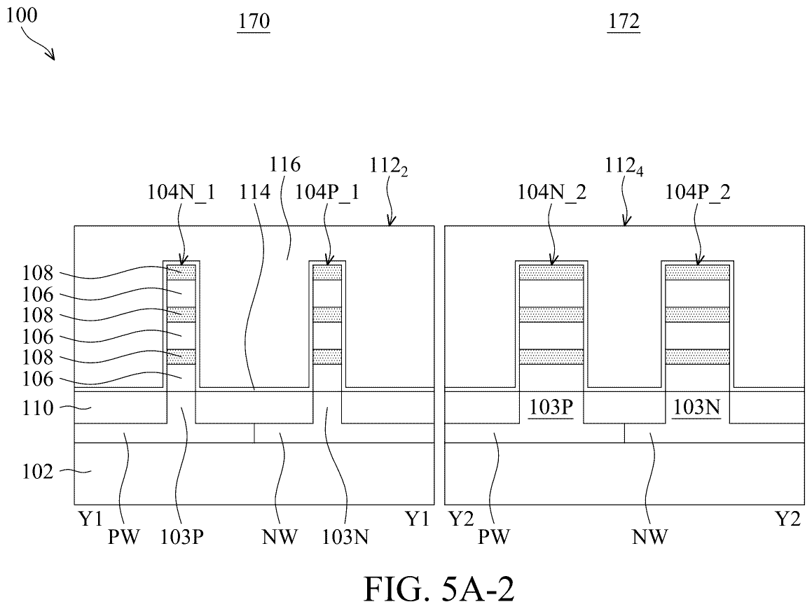

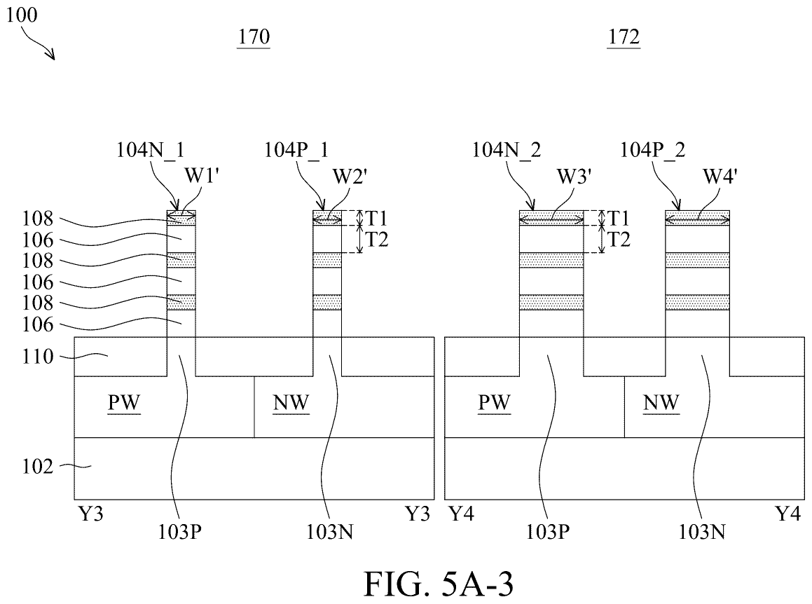

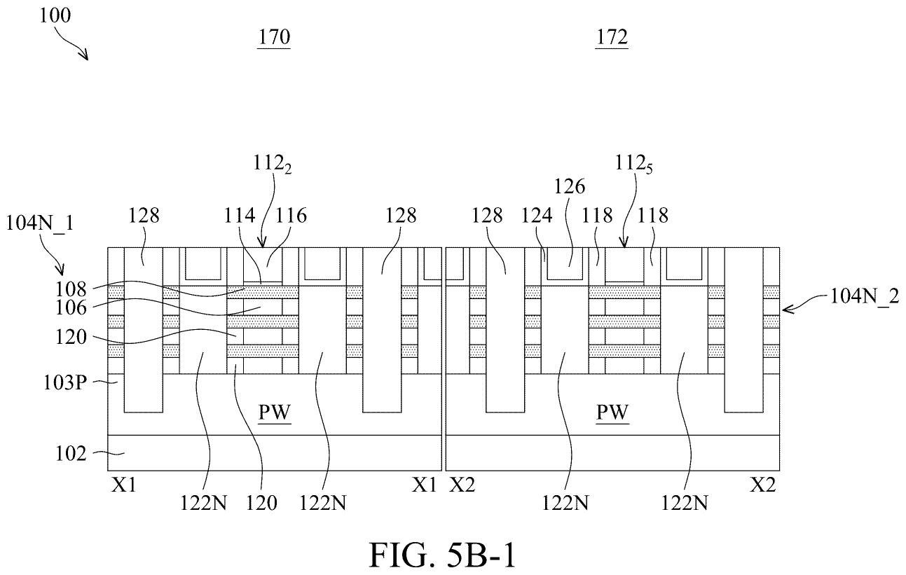

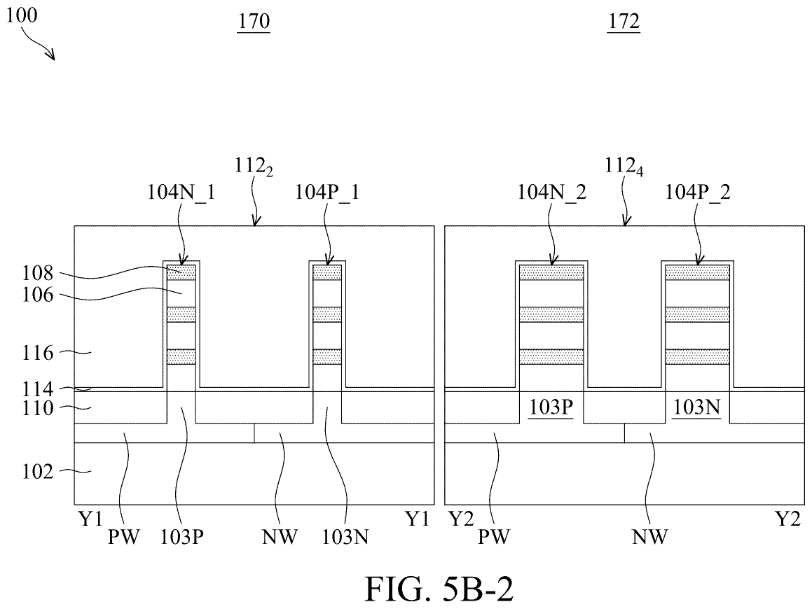

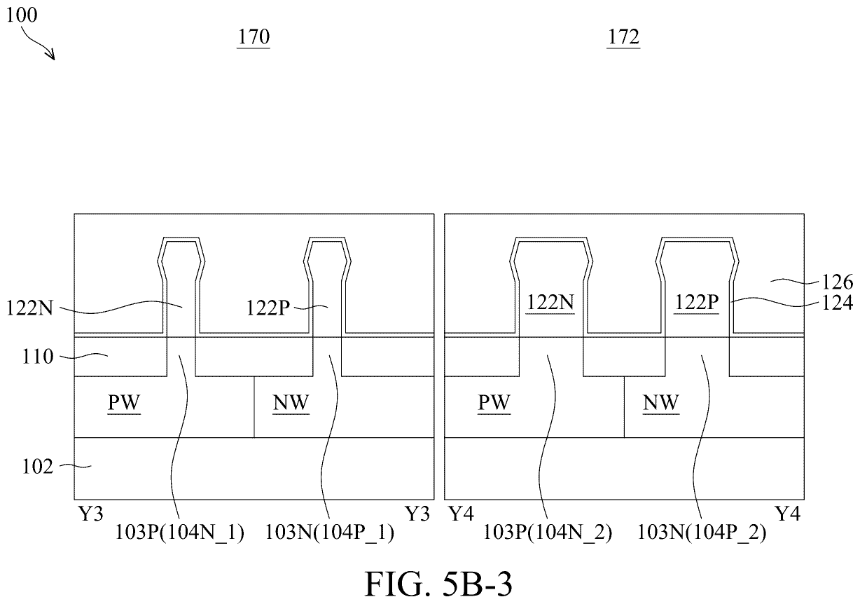

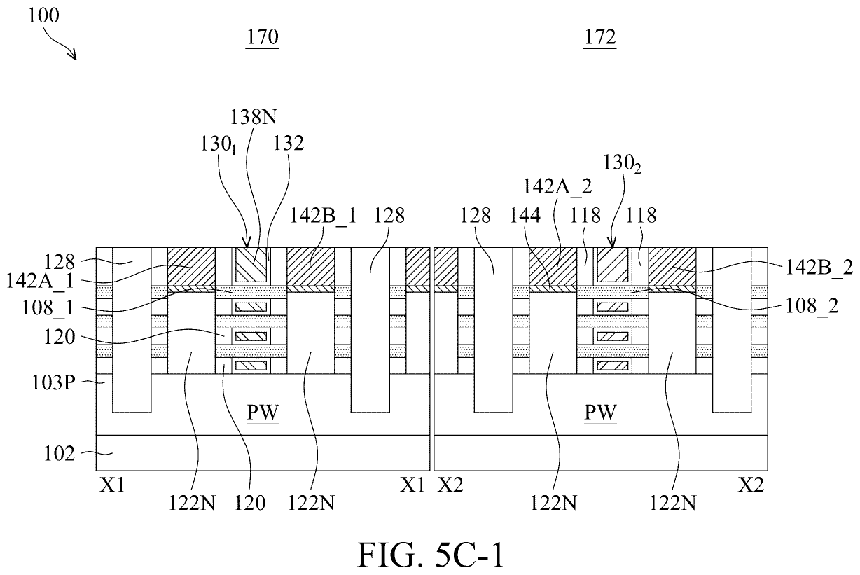

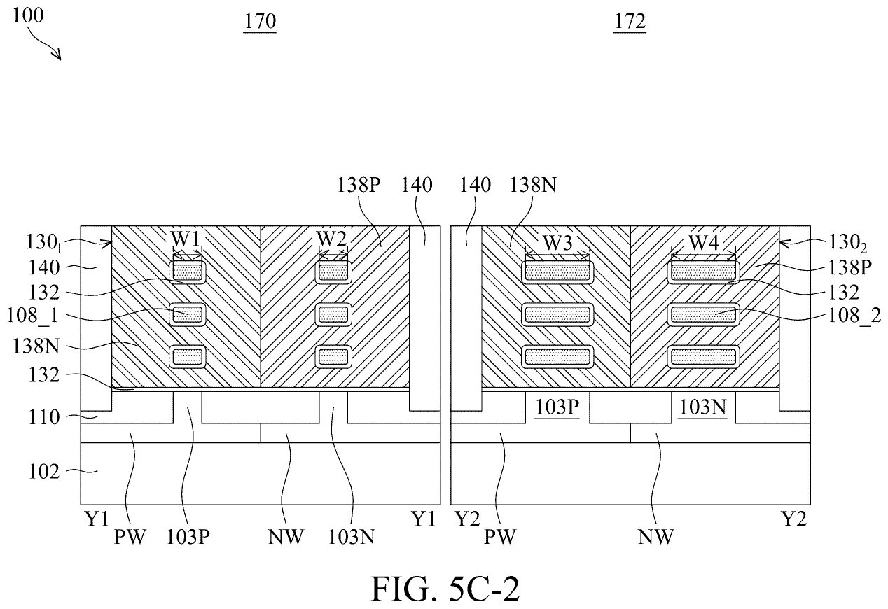

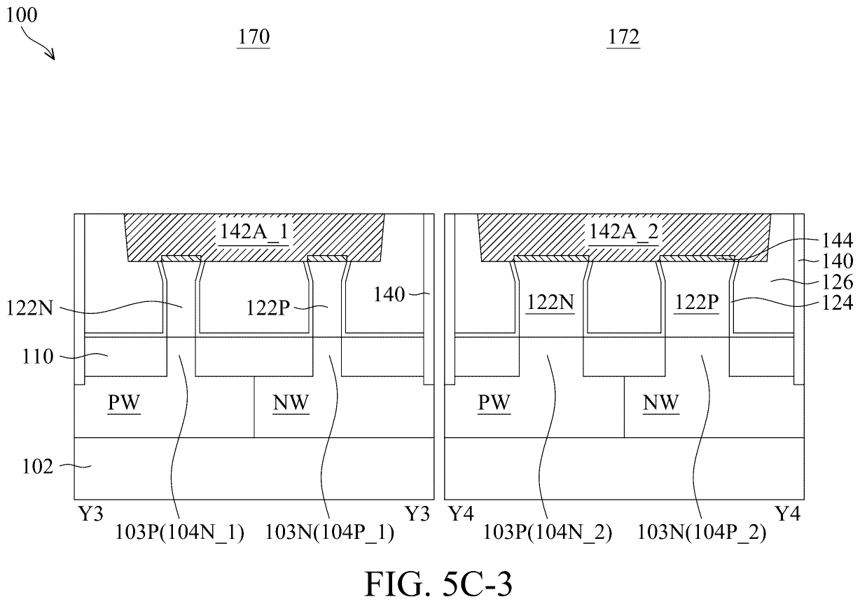

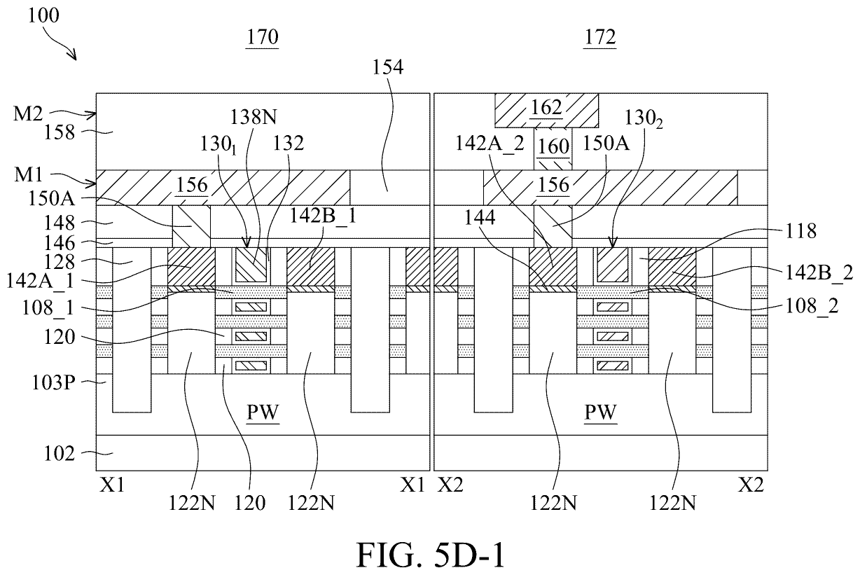

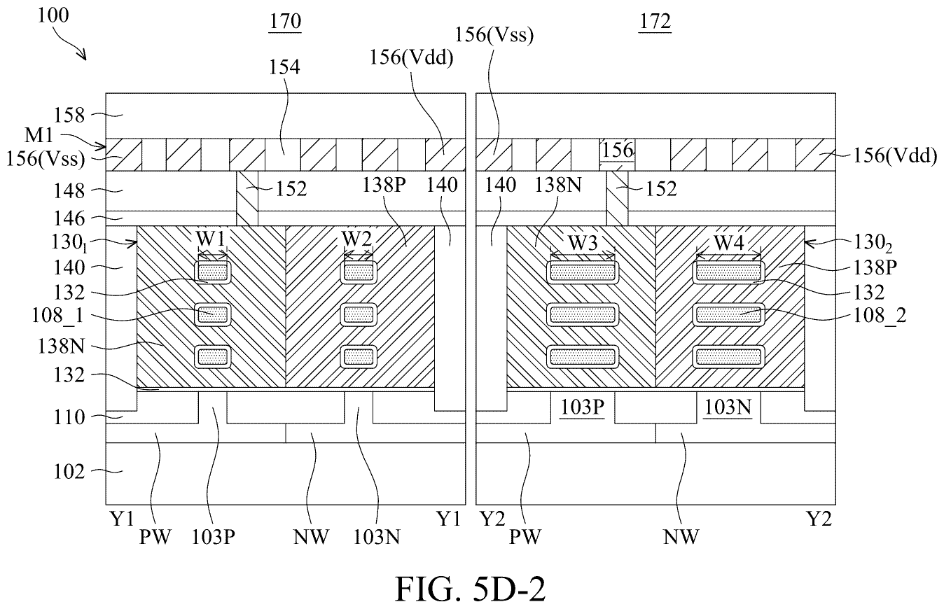

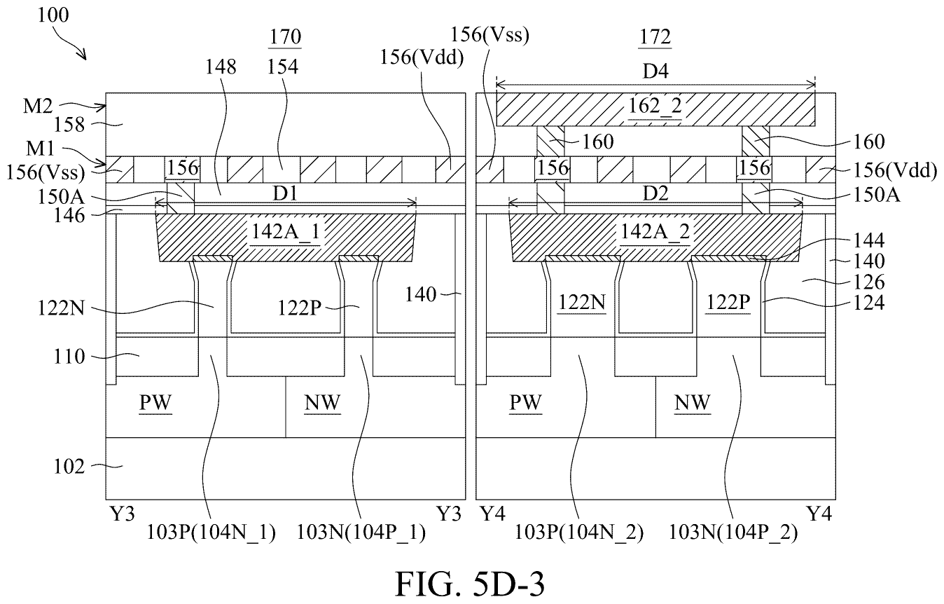

Gate spacer layers 118 are formed on the opposite sides of the dummy gate structure 112, as shown in FIG. 5A-1, in accordance with some embodiments. The gate spacer layers 118 are used to offset the subsequently formed source/drain features and separate the source/drain features from the gate structure, in accordance with some embodiments. In some embodiments, the gate spacer layers 118 are made of dielectric material, such as silicon-containing dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN).

In some embodiments, the gate spacer layers 118 include air gaps and/or a porous version of the above-mentioned dielectric materials. In some embodiments, the formation of the gate spacer layers 118 includes globally and conformally depositing a dielectric material for the gate spacer layers 118 over the semiconductor structure 100 using ALD, CVD (such as LPCVD, PECVD or HDP-CVD or a combination thereof, followed by an anisotropic etching process, in accordance with some embodiments. After the anisotropic etching process, the vertical portions of the dielectric material left remaining on the opposite sides of the dummy gate structure 112 form the gate spacer layers 118, in accordance with some embodiments. In some embodiments, the gate spacer layer 118 has a thickness (in the X direction) in a range from about 3 nm to about 12 nm.

FIGS. 5B-1, 5B-2 and 5B-3 illustrate the semiconductor structure 100 after the formation of inner spacer layers 120, source/drain features 122N and 122P, a contact etching stop layer 124, a first interlayer dielectric layer 126, and fin-cut structures 128 respectively corresponding to line X1-X1 and line X2-X2, line Y1-Y1 and line Y2-Y2, and line Y3-Y3 and line Y4-Y4.

An etching process is performed to recess the source/drain regions of the active regions 104, thereby forming source/drain recesses, in accordance with some embodiments. The etching process may be an anisotropic etching process such as dry plasma etching, an isotropic etching process such as dry chemical etching, remote plasma etching or wet chemical etching, or a combination thereof. The gate spacer layers 118 and the dummy gate structures 112 may serve as etch masks such that the source/drain recesses are formed self-aligned on opposite sides of the dummy gate structures 112, in accordance with some embodiments.

Afterward, an etching process is performed to laterally recess, from the source/drain recesses, the first semiconductor layers 106 of the active regions 104 to form notches, and then inner spacer layers 120 are formed in the notches, as shown in FIG. 5B-1, in accordance with some embodiments. The inner spacer layers 120 abut the recessed side surfaces of the first semiconductor layers 106, in accordance with some embodiments. In some embodiments, the inner spacer layers 120 are located directly below the gate spacer layers 118, in accordance with some embodiments. The inner spacer layers 120 may avoid the source/drain features and the gate stack from being in direct contact and are configured to reduce the parasitic capacitance between the gate stack and the source/drain features (i.e., Cgs and Cgd), in accordance with some embodiments.

In some embodiments, the inner spacer layers 120 are made of a dielectric material, such as silicon oxide (SiO₂), silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), a multilayer thereof, or a combination thereof. In some embodiments, the inner spacer layers 120 are formed by depositing a dielectric material to overfill the notches using ALD, CVD (such as PECVD, LPCVD or HARP), and then etching away the dielectric material outside the notches using an anisotropic etching process such as dry plasma etching, an isotropic etching process such as dry chemical etching, remote plasma etching or wet chemical etching, or a combination thereof. In some embodiments, the inner spacer layers 120 have a high dielectric constant than the gate spacer layers 118. In some embodiments, the inner spacer layers 120 have thickness (in the X direction) in a range from about 2 nm to about 10 nm.

Source/drain features 122N and 122P are grown in the source/drain recesses on exposed semiconductor surfaces of the second semiconductor layers 108 and the lower fin elements 103N and 103P using epitaxial growth process, as shown in FIGS. 5B-1 and 5B-3, in accordance with some embodiments. The epitaxial growth process may be MBE, MOCVD, or VPE, another suitable technique, or a combination thereof. In some embodiments, the source/drain features 122N have a different electrically conductive type than the source/drain features 122P.

In some embodiments, the source/drain features 122N and the source/drain features 122P may be formed separately. For example, a patterned mask layer may be formed to cover the semiconductor structure 100 over the n-type well, and then the source/drain features 122N are grown. Afterward, the patterned mask layer may be removed. Similarly, a patterned mask layer is formed to cover the semiconductor structure 100 over the p-type well, and then the source/drain features 122P are grown. Afterward, the patterned mask layer may be removed.

In some embodiments, the source/drain features 122N and 122P are in-situ doped during the epitaxial processes. In some embodiments, the source/drain features 122N are doped with the n-type dopant during the epitaxial growth process. For example, the n-type dopant may be phosphorous (P) or arsenic (As). For example, the n-type source/drain features 122N may be the epitaxially grown silicon phosphorous (SiP), silicon carbon (SiC), silicon phosphorous carbon (SiPC), silicon phosphorous arsenic (SiPAs), silicon arsenic (SiAs), silicon (Si), or a combination thereof doped with phosphorous and/or arsenic. In some embodiments, the concentrations of the dopant (e.g., P) in the source/drain features 122N are in a range from about 2×10¹⁹ cm⁻³ to about 3×10²¹ cm⁻³.

In some embodiments, the source/drain features 122P are doped with the p-type dopant during the epitaxial growth process. For example, the p-type dopant may be boron (B) or BF₂. For example, the p-type source/drain features 122P may be the epitaxially grown silicon germanium (SiGe), silicon germanium carbon (SiGeC), germanium (Ge), silicon (P), or a combination thereof doped with boron (B). In some embodiments, the concentrations of the dopant (e.g., B) in the source/drain features 122P are in a range from about 1×10¹⁹ cm⁻³ to about 6×10²⁰ cm⁻³. In some embodiments, the n-type source/drain features 122N and the p-type source/drain features 122P are made of different epitaxial materials. For example, the n-type source/drain features 122N are made of SiP, and the p-type source/drain features 122P are made of SiGe.

A contact etching stop layer 124 is formed over the source/drain features 122N and 122P, as shown in FIGS. 5B-1 and 5B-3, in accordance with some embodiments. In some embodiments, the contact etching stop layer 124 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 124 is globally and conformally deposited over the semiconductor structure 100 using CVD (such as LPCVD, PECVD, HDP-CVD, or HARP), ALD, another suitable method, or a combination thereof.

A first interlayer dielectric layer 126 is formed over the contact etching stop layer 124, as shown in FIGS. 5A-1 and 5C-2, in accordance with some embodiments. In some embodiments, the first interlayer dielectric layer 126 is made of dielectric material, such as un-doped silicate glass (USG), or doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the first interlayer dielectric layer 126 and the contact etching stop layer 124 are made of different materials and have a great difference in etching selectivity. In some embodiments, the dielectric material for the first interlayer dielectric layer 126 is deposited using a technique such as CVD (such as HDP-CVD, PECVD, HARP or FCVD), another suitable technique, or a combination thereof.

The dielectric materials for the contact etching stop layer 124 and the first interlayer dielectric layer 126 formed above the dummy gate electrode layer 116 are removed using a technique such as CMP until the dummy gate electrode layer 116 is exposed, in accordance with some embodiments.

Fin-cut structures 128 are formed to replace the dummy gate structures 112₁, 112₃, 112₄ and 112₆, as shown in FIG. 5B-1, in accordance with some embodiments. The fin-cut structures 128 pass through the dummy gate structures 112₁, 112₃, 112₄ and 112₆ and the underlying active regions 104N and 104P, thereby cutting through the active regions 104N and 104P, in accordance with some embodiments. In some embodiments, the fin-cut structures 128 extend in the Y direction. The fin-cut structures 128 may be also referred to as cut poly gate on oxide definition edge (CPODE) pattern.

The fin-cut structures 128 are made of a dielectric material such as silicon oxide (SiO₂), silicon oxynitride (SiON), silicon nitride (SiN), silicon carbon nitride (SiCN), silicon oxycarbonitride (SiOCN), oxygen-doped silicon carbonitride (Si(O)CN), or a combination thereof. In some embodiments, the fin-cut structures 128 include dielectric material with k-value greater than 7.9, such as LaO, AlO, AlON, ZrO, HfO, ZnO, ZrN, ZrAlO, TiO, TaO, YO, TaCN, or a combination thereof.

The formation of the fin-cut structures 128 includes patterning the dummy gate structures 112 and the active regions 104N and 104P using photolithography and etching processes to form cutting trenches, depositing a dielectric material for the fin-cut structures 128 to overfill the cutting trenches using CVD (such as LPCVD, PECVD, HDP-CVD, or HARP), ALD, another suitable method, or a combination thereof, in accordance with some embodiments. A planarization process (e.g., CMP, etching back process, or a combination thereof) is then performed on dielectric material formed until the first interlayer dielectric layer 126 is exposed, in accordance with some embodiments.

FIGS. 5C-1, 5C-2 and 5C-3 illustrate the semiconductor structure 100 after the formation of final gate stacks 130 (including 130₁ and 130₂), gate-cut structures 140, contact plugs 142A and 142B respectively corresponding to line X1-X1 and line X2-X2, line Y1-Y1 and line Y2-Y2, and line Y3-Y3 and line Y4-Y4.

One or more etching processes are performed to remove the dummy gate structures 112₂ and 112₅ to form gate trenches and remove the first semiconductor layers 106 of the active regions 104N and 104P to form gaps, in accordance with some embodiments. In some embodiments, the gate trenches expose the channel regions of the active regions 104N and 104P. In some embodiments, the gate trenches further expose the sidewalls of the gate spacer layers 118 facing the channel region. In some embodiments, the gaps expose the inner sidewalls of the inner spacer layers 120 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 form nanostructures 108 (including 108_1 in the first cell region 170 and 108_2 in the second cell region 172), as shown in FIGS. 5D-1 and 5D-2, in accordance with some embodiments. The nanostructures 108 which are vertically stacked function as a set of channel layers for a transistor, in accordance with some embodiments. As the term is used herein, “nanostructures” refers to the semiconductor layers with cylindrical shape, bar shaped and/or sheet shape.

In some embodiments, the nanostructures 108_1 in the p-type well PW have a channel width W1 and the nanostructures 108_2 in the p-type well PW have a channel width W3. In some embodiments, the channel width W3 is greater than the channel width W1. In some embodiments, the ratio (W3/W1) of the channel width W3 to the channel width W1 is in a range from about 1.5 to about 8. In some embodiments, the nanostructures 108_1 in the n-type well NW have a channel width W2 and the nanostructures 108_2 in the n-type well NW have a channel width W4. In some embodiments, the channel width W4 is greater than the channel width W2. In some embodiments, the ratio (W4/W2) of the channel width W4 to the channel width W2 is in a range from about 1.5 to about 8.

Final gate stacks 130 (including 130₁ and 130₂) are formed in the gate trenches and gaps, and are thereby wrapping around the nanostructures 108, as shown in FIGS. 5C-1 and 5C-2, in accordance with some embodiments. The final gate stack 130₁ is formed in the first cell region 170, and the final gate stack 130₂ is formed in the second cell region 172, in accordance with some embodiments. In some embodiments, the final gate stacks 130 extend in the Y direction. The final gate stacks 130 engage the channel region so that current can flow between the source/drain regions during operation. In some embodiments, each of the final gate stacks 130 includes a gate dielectric layer 132 and a metal gate electrode layer.

The gate dielectric layer 132 is formed to wrap around the nanostructures 108, in accordance with some embodiments. The gate dielectric layer 132 is further formed along the upper surface of the isolation structure 110, in accordance with some embodiments. The gate dielectric layer 132 is also conformally formed along the sidewalls of the gate spacer layers 118 and the inner spacer layers 120 facing the channel region, in accordance with some embodiments.

The gate dielectric layer 132 includes an interfacial layer and a high-k dielectric layer on the interfacial layer, in accordance with some embodiments. The interfacial layer is formed on the exposed surfaces of the nanostructures 108 and the exposed upper surfaces of the lower fin elements 103N and 103P, in accordance with some embodiments. In some embodiments, the interfacial layer is made of a chemically formed silicon oxide, which is formed using one or more cleaning processes. In some embodiments, the high-k dielectric layer is dielectric material with high dielectric constant (k value), for example, greater than 7.9, such as greater than 13. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Si₃N₄, oxynitrides (SiON), a combination thereof, or another suitable material. The high-k dielectric layer may be deposited using ALD, PVD, CVD, and/or another suitable technique.

The metal gate electrode layer is formed to fill remainders of the gate trenches, in accordance with some embodiments. The metal gate electrode layer includes an n-type work function metal material 138N in the p-type well PW and a p-type work function metal material 138P formed in the n-type well NW, in accordance with some embodiments. In some embodiments, the work function metal materials 138N and 138P have selected work functions to enhance the device performance (e.g., threshold voltage) for n-channel FETs or p-channel FETs. The work function metal materials 138N and 138P may be formed separately.

In some embodiments, the work function metal materials 138N and 138P are made of more than one conductive material, such as TiN, TaN, TiAl, TiAlN, TaAl, TaAlN, TaAlC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof. The work function metal material 138N includes a different combination of materials than the work function metal material 138P, in accordance with some embodiments. The work function metal materials 138N and 138P may be formed using ALD, PVD, CVD, e-beam evaporation, or another suitable technique.

A planarization process such as CMP may be performed on the semiconductor structure 100 to remove the materials of the gate dielectric layer 132 and the metal gate electrode layer formed above the first interlayer dielectric layer 126, in accordance with some embodiments. The final gate stacks 130 that are wrapped around the nanostructures 108 combine with the neighboring source/drain features 122N or 122P to form nanostructure transistors. In some embodiments, the transistors formed on the nanostructures 108_1 and 108_2 in the p-type well PW are the n-channel nanostructure transistors (e.g., NMOSFET shown in FIG. 2B), and the transistors formed on the nanostructures 108_1 and 108_2 in the n-type well NW are the p-channel nanostructure transistors (e.g., PMOSFET shown in FIG. 2B).

Gate-cut structures 140 are formed through the final gate stacks 130, the fin-cut structures 128 and the gate spacer layers 118, the contact etching stop layer 124 and the first interlayer dielectric layer 126, as shown in FIGS. 5B-2 and 5B-3, in accordance with some embodiments. In some embodiments, the gate-cut structures 140 extend in the X direction. The final gate stacks 130 are cut through by the gate-cut structures 140 into several segments which are physically and electrically isolated from each other, in accordance with some embodiments. The gate-cut structures 140 may be also referred to as cut metal gate (CMG) pattern.

The gate-cut structures 140 are made of a dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate-cut structures 140 include dielectric material with a dielectric constant value greater than 7.9, such as LaO, AlO, AlON, ZrO, HfO, ZnO, ZrN, ZrAlO, TiO, TaO, YO, TaCN, or a combination thereof. The formation of the gate-cut structures 140 includes patterning the semiconductor structure 100 to form gate-cut openings using photolithography and etching processes, depositing a dielectric material to overfill the gate-cut openings, in accordance with some embodiments. A planarization process (e.g., CMP, etching back process, or a combination thereof) is then performed on the dielectric material until the first interlayer dielectric layer 126 is exposed, in accordance with some embodiments.

The contact plugs 142A and 142B are formed through the first interlayer dielectric layer 126 and the contact etching stop layer 124 and land on the source/drain features 122N and 122P, in accordance with some embodiments. The contact plug 142A_1 serves as the drain node of the nanostructure transistors in the first cell region 170, and the contact plug 142A_2 serves as the drain node of the nanostructure transistors in the second cell region 172, in accordance with some embodiments. The contact plugs 142B 1 serve as the source node of the nanostructure transistors in the first cell region 170, and the contact plugs 142A_2 serve as the source node of the nanostructure transistors in the second cell region 172, in accordance with some embodiments.

In some embodiments, the formation of the contact plugs 142A and 142B includes patterning the semiconductor structure 100 to form contact openings using photolithography and etching processes until the source/drain features 122N/122P are exposed. Silicide layers 144 are formed on the exposed surfaces of the source/drain features 122N and 122P, in accordance with some embodiments. In some embodiments, the silicide layers 144 are made of WSi, NiSi, TiSi and/or CoSi. In some embodiments, the formation of the silicide layers 144 includes depositing a metal material followed by one or more annealing processes. The semiconductive material (e.g., Si) from the source/drain features 122N and 122P reacts with the metal material to form the silicide layers 144, in accordance with some embodiments. Unreacted metal material is then removed, e.g., using wet etching.

Afterward, one or more conductive materials for the contact plugs 142A and 142B are deposited using CVD, PVD, e-beam evaporation, ALD, ECP, ELD, another suitable method, or a combination thereof to overfill the contact openings, in accordance with some embodiments. The one or more conductive materials over the second interlayer dielectric layer 148 are planarized using, for example, CMP. The contact plugs 142A and 142B may have a multilayer structure. For example, a barrier/adhesive layer (not shown) may optionally be deposited along the sidewalls and the bottom surfaces of the contact openings. The barrier/adhesive layer may be made of tantalum (Ta), tantalum nitride (TaN), titanium (Ti), titanium nitride (TiN), cobalt tungsten (CoW), another suitable material, or a combination thereof. A metal bulk layer is then deposited on the barrier/adhesive layer (if formed) to fill the remainder of the contact openings. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

FIGS. 5D-1, 5D-2 and 5D-3 illustrate the semiconductor structure 100 after the formation of a mask layer 146, a second interlayer dielectric layer 148, first-level vias 150A/B and 152, a first intermetal dielectric layer 154, a first-level metal layer M1, a second intermetal dielectric layer 158, second-level vias 160 and a second metal layer 162 respectively corresponding to line X1-X1 and line X2-X2, line Y1-Y1 and line Y2-Y2, and line Y3-Y3 and line Y4-Y4.

A mask layer 146 and a second interlayer dielectric layer 148 are sequentially formed over the semiconductor structure 100, as shown in FIGS. 5D-1 to 5D-3, in accordance with some embodiments. In some embodiments, the mask layer 146 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, the second interlayer dielectric layer 148 is made of dielectric material, such as USG, BPSG, FSG, PSG, BSG, and/or another suitable dielectric material. In some embodiments, the mask layer 146 and the second interlayer dielectric layer 148 are deposited using CVD (such as HDP-CVD, PECVD, HARP or FCVD), another suitable technique, or a combination thereof.

Vias 150A and 150B are formed through the second interlayer dielectric layer 148 and the mask layer 146 and land on the contact plugs 142A and 142B, and vias 152 are formed through the second interlayer dielectric layer 148, and the mask layer 146 and lands on the gate stack 130, as shown in FIGS. 5D-1 to 5D-3, in accordance with some embodiments.

In some embodiments, the formation of the vias 150A, 150B and 152 includes patterning the semiconductor structure 100 to form via openings using photolithography and etching processes. Afterward, one or more conductive materials are deposited using CVD, PVD, e-beam evaporation, ALD, ECP, ELD, another suitable method, or a combination thereof to overfill the via openings, in accordance with some embodiments. The one or more conductive materials over the upper surface of the second interlayer dielectric layer 148 are planarized using, for example, CMP.

The vias 150A, 150B and 152 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

A first intermetal dielectric layer 154 is formed over the vias 152A, 152B and 154 and the second interlayer dielectric layer 148, and lines 156 of a first-level metal layer M1 are formed through the first intermetal dielectric layer 154, as shown in FIGS. 5D-1 to 5D-3, in accordance with some embodiments. The lines 156 extend in the X direction, in accordance with some embodiments.

In some embodiments, the first intermetal dielectric layer 154 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the first intermetal dielectric layer 154 is made of an extremely low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SILK, or porous silicon oxide (SiO₂). In some embodiments, the first intermetal dielectric layer 154 is formed using CVD (such as LPCVD, HARP, and FCVD), ALD, spin-on coating, another suitable method, or a combination thereof. A post-curing process (e.g., UV curing) may be performed on the as-deposited ELK dielectric material for the first intermetal dielectric layer 154 to form a porous structure.

In some embodiments, the formation of the first-level metal layer M1 includes patterning the semiconductor structure 100 to form trenches using photolithography and etching processes. Afterward, one or more conductive materials are deposited using CVD, PVD, e-beam evaporation, ALD, ECP, ELD, another suitable method, or a combination thereof to overfill the trenches, in accordance with some embodiments. The one or more conductive materials over the upper surface of the first intermetal dielectric layer 154 are planarized using, for example, CMP. The lines 156 may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

A second intermetal dielectric layer 158 is formed over the first-level metal layer M1 and the first intermetal dielectric layer 154, and second-level vias 160 and lines 162 of a second-level metal layer M2 are formed through the second intermetal dielectric layer 158 as shown in FIGS. 5D-1 to 5D-3, in accordance with some embodiments. Although FIGS. 5D-1 to 5D-3 only show one line 162 of the second-level metal layer M2 in the second cell region 172, the second-level metal layer M2 may include several conductive lines 162, in accordance with some embodiments. The lines 156 extend in the Y direction, in accordance with some embodiments.

In the second cell region 172, the drain-node contact plug 142A_2 is electrically connected in parallel to the line 162_2 of the second-level metal layer M2 through two second-level vias 160, two lines 156 of the first-level metal layer M1 and two first-level vias 150A, as shown in FIG. 5D-3, in accordance with some embodiments.

In some embodiments, the material and the formation of the second intermetal dielectric layer 158 are the same as or similar to the material and the formation of the first intermetal dielectric layer 154. In some embodiments, the second-level vias 160 and the second-level metal layer M2 are formed using single damascene and/or dual damascene processes. For example, in a dual damascene process, both trenches and via holes are formed in the second intermetal dielectric layer 158, with the via holes underlying and connected to the trenches. The conductive material is then deposited to fill the trenches and the via holes to form lines 162 and vias 160, respectively. The conductive material may have a multilayer structure, for example, including a barrier/adhesive layer and a metal bulk layer. The barrier layer may be made of Ta, TaN, Ti, TiN, CoW, another suitable material, or a combination thereof. In some embodiments, the metal bulk layer is made of one or more conductive materials, such as Co, Ni, W, Ti, Ta, Cu, Rh, Ir, Pt, Al, Ru, Mo, or a combination thereof.

It should be understood that the semiconductor structure 100 may undergo further CMOS processes to form various features over the semiconductor structure 100, such as third-level vias and metal layer, fourth-level vias and metal layer, etc.

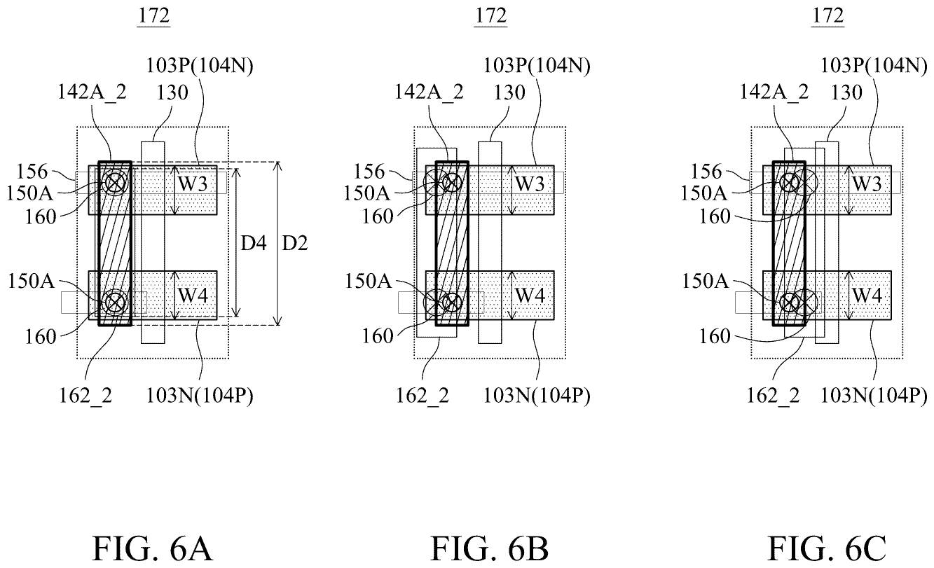

FIGS. 6A, 6B and 6C illustrate the various configurations between a drain-node contact plug 142A_2 in a second cell region 172 and a line 162_2 of a second-level metal layer (M2), in accordance with some embodiments of the disclosure.

In some embodiments, the line 162_2 electrically connected to the drain-node contact plug 142A_2 has a dimension D4 that is less than the dimension D2 of the contact plug 142A_2, as shown in FIG. 6A. The line 162_2 is offset away from the gate stack 130, and the contact plug 142A_2 includes a portion inside the area of the line 162_2 and another portion outside the area of the line 162_2, as shown in FIG. 6B. The line 162_2 is offset toward the gate stack 130, and the contact plug 142A_2 includes a portion inside the area of the line 162_2 and another portion outside the area of the line 162_2, as shown in FIG. 6C. If the line 162_2 is offset too far (e.g., the contact plug 142A_2 is completely outside the area of the line 162_2), the routing of other lines 162 of the second-level metal layer may be affected.

FIGS. 7-1 and 7-2 are cross-sectional views of a semiconductor structure 100, in accordance with some embodiments of the disclosure. The embodiments of FIGS. 7-1 and 7-2 are similar to the embodiments of the FIGS. 5D-1 to 5D-3 except that a dielectric isolation structure 202 is formed between the source/drain feature 122N/P and the lower fin element 103P/N.

After the inner spacer layers 120 are formed, dielectric isolation layers 202 are formed on the lower fin elements 103P and 103N, as shown in FIGS. 7-1 and 7-2, in accordance with some embodiments. In some embodiments, the dielectric isolation layers 202 are used to reduce the leak caused by the planar transistors formed by the lower fin elements 103N and 103P. In some embodiments, the dielectric isolation layers 202 are made of dielectric material silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the dielectric isolation layers 202 are formed by deposition and etching-back processes.

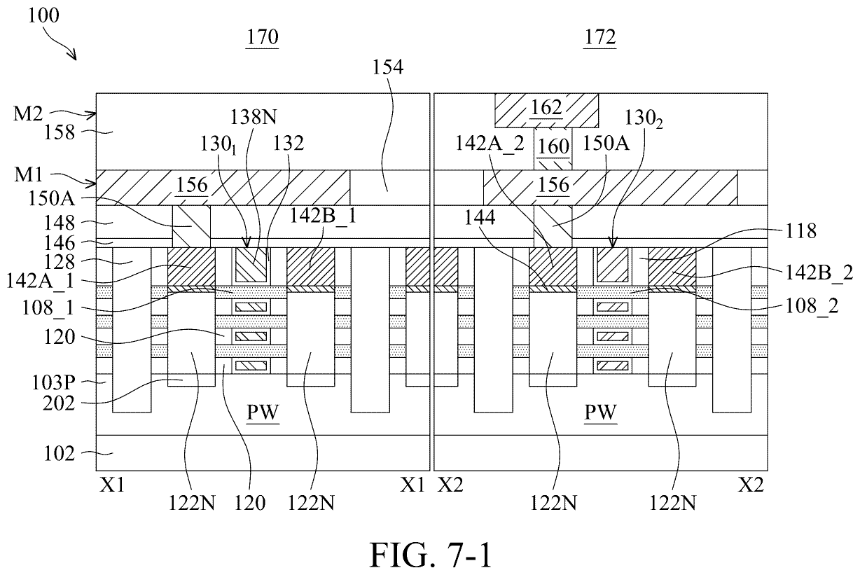

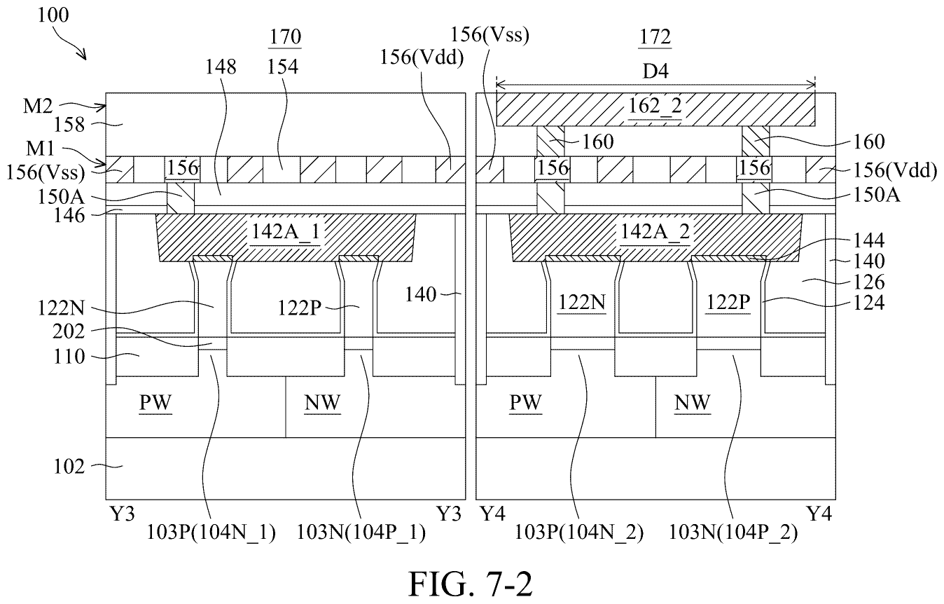

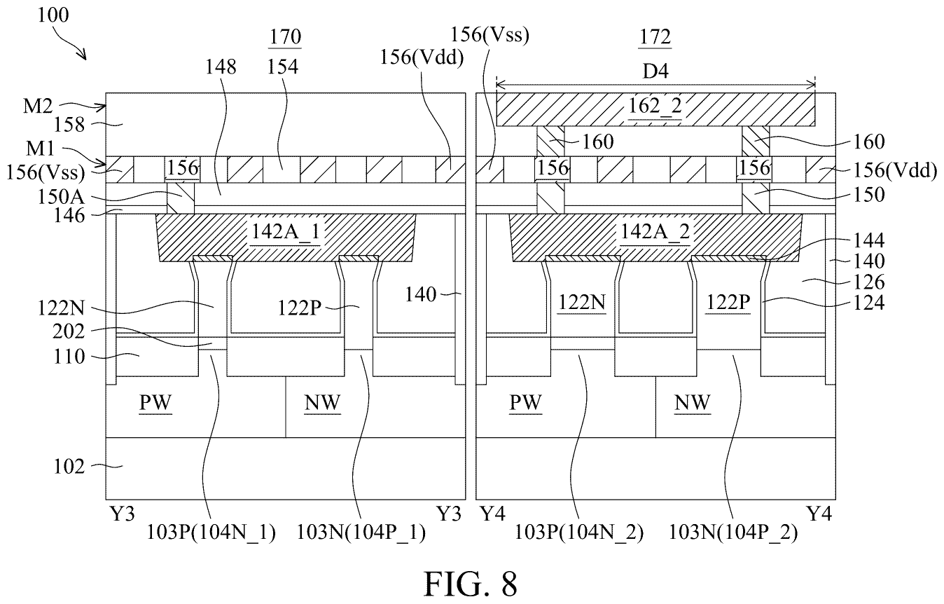

FIG. 8 is a cross-sectional view of a semiconductor structure 100, in accordance with some embodiments of the disclosure. The embodiments of FIG. 8 are similar to the embodiments of the FIGS. 7-2 except that the dielectric isolation structure 202 is removed from the n-type well NW. In some embodiments where the p-type source/drain features 122P are made of SiGe, the source/drain features 122P formed on the semiconductor surface of the lower fin element 103N may impart more stress or strain to the channel regions than the source/drain features 122P formed on the dielectric surface. As a result, the dielectric isolation structure 202 is removed from the n-type well NW using an etching process.

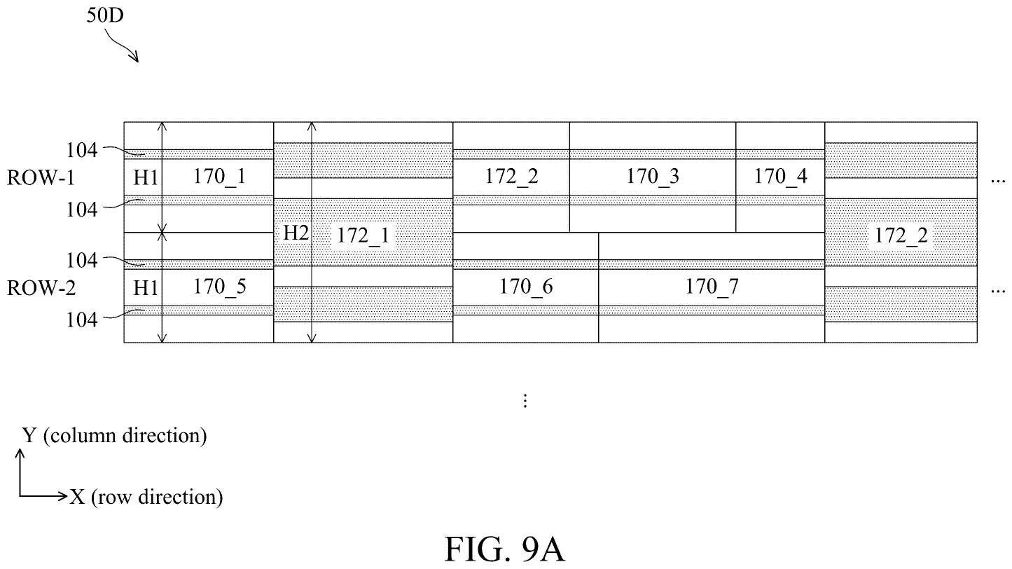

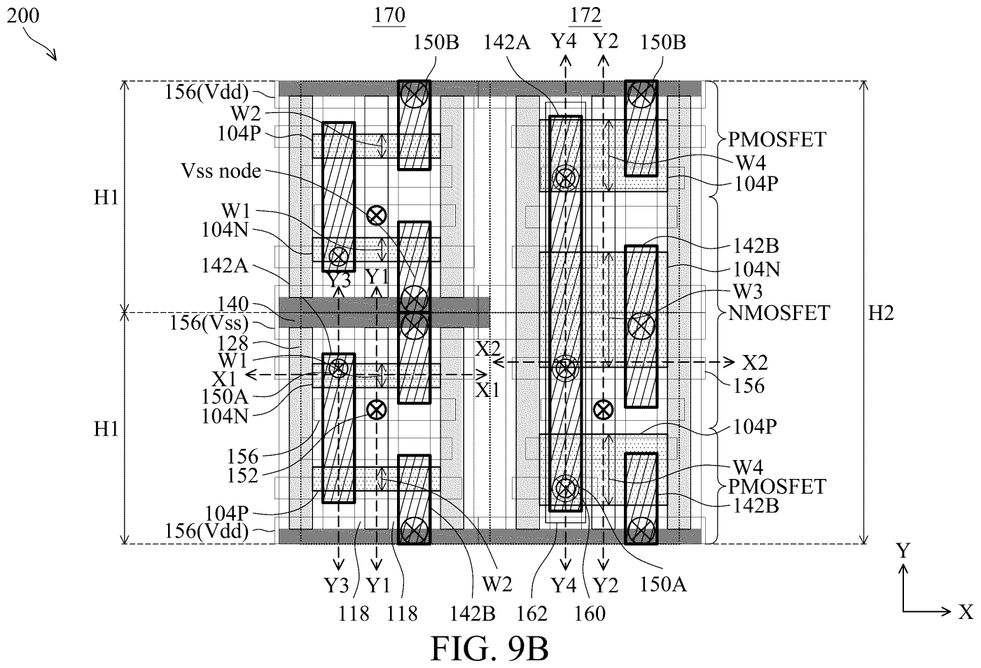

FIG. 9A is a top view of a standard cell array 50D, in accordance with some embodiments of the disclosure.

The standard cell array 50D includes a plurality of first cell regions 170 and a plurality of second cell regions 172 arranged in rows and in columns, as shown in FIG. 9A, in accordance with some embodiments. The first cell regions 170 include high-density circuits, and the second cell regions include high-current circuits, in accordance with some embodiments. The cell height H1 of the first cell region 170 is less than the cell height H2 of the second cell region 172, in accordance with some embodiments. In specific, the ratio of the cell height H2 to the cell height H1 is about 2. As a result, two first cell regions 170 are matched with one second cell region 172 in the column direction, and thus the first cell regions 170 and the second cell regions 172 can be arranged in the same cell array, in accordance with some embodiments. In some embodiments, the high-current circuits in the cell region 50D may provide as high on-state current as possible due to lower area utilization constraints.

FIG. 9B is a layout (top view) illustrating a semiconductor structure 200 including two first cell regions 170 and one second cell region 172 in the standard cell array 50D of FIG. 9A, in accordance with some embodiments of the disclosure. The first cell regions 170 may be separate from the second cell region 172, or alternatively abut and/or are immediately adjacent to the second cell region 172.

In some embodiments, the channel width W3 of the active region 104N in the second cell region 172 is greater than the channel width W1 of the active region 104N in the first cell region 170. In some embodiments, the ratio (W3/W1) of the channel width W3 to the channel width W1 is in a range from about 2 to about 8. In some embodiments, the channel width W4 of the active region 104P in the second cell region 172 is greater than the channel width W2 of the active region 104P in the first cell region 170. In some embodiments, the ratio (W4/W2) of the channel width W4 to the channel width W2 is in a range from about 2 to about 8.

In some embodiments, the ratio (W3/W1) is greater than the ratio (W4/W2). In some other embodiments, the ratio (W3/W1) may be less than the ratio (W4/W2). In some embodiments where the first cell regions 170 and the second cell region 172 are abutted, and at least two fin-cut structures 128 correspond to the boundary between the first cell regions 170 and the second cell region 172. This is because as the channel width ratio increases, the transition length of the jog of the active region 104 becomes longer.

In the second cell region 172, one contact plug 142A is electrically connected to the drain nodes (or terminals) of three nanostructure transistors (e.g., one NMOSFET and two PMOSFETs), in accordance with some embodiments. In the second cell region 172, three contact plugs 142B are electrically connected to the respective source nodes (or terminals) of the nanostructure transistors, in accordance with some embodiments. In some embodiments, the Vdd and Vss power rails 156 may continuously extend through the cell regions 170 and 172. The Vdd power rails 156 extend along and overlap the boundaries of the second cell region 172 with respect to the Y direction, and the Vss power rail 156 passes through the interior of the second cell region 172, in accordance with some embodiments.

In the second cell region 172, the drain-node contact plug 142A is electrically connected in parallel to a line 162 of the second-level metal layer (M2) through three second-level vias 160, three lines 156 of the first-level metal layer (M1) and three first-level vias 150A, in accordance with some embodiments. Although not shown, the drain-node contact plug 142A in the first cell region 170 is electrically connected in series to a line 162 of the second-level metal layer (M2).

FIGS. 10-1, 10-2 and 10-3 are cross-sectional views of a semiconductor structure 200, in accordance with some embodiments of the disclosure. FIGS. 10-1, 10-2 and 10-3 illustrate the semiconductor structure 200 respectively corresponding to line X1-X1 and line X2-X2, line Y1-Y1 and line Y2-Y2, and line Y3-Y3 and line Y4-Y4 of FIG. 9B. The semiconductor structure 200 includes a first cell region 170 and a second cell region 172 which may be the cells 170 and 172 in the cell array 50D of FIG. 9A, in accordance with some embodiments. The formation of the semiconductor structure 200 may be similar to the formation of the semiconductor structure 100 described above in FIGS. 5A-1 to 5D-3, in accordance with some embodiments.

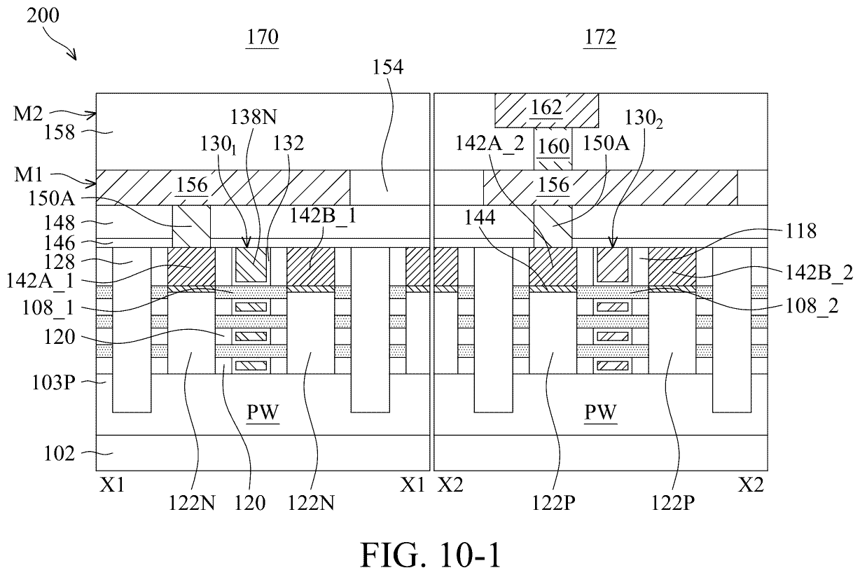

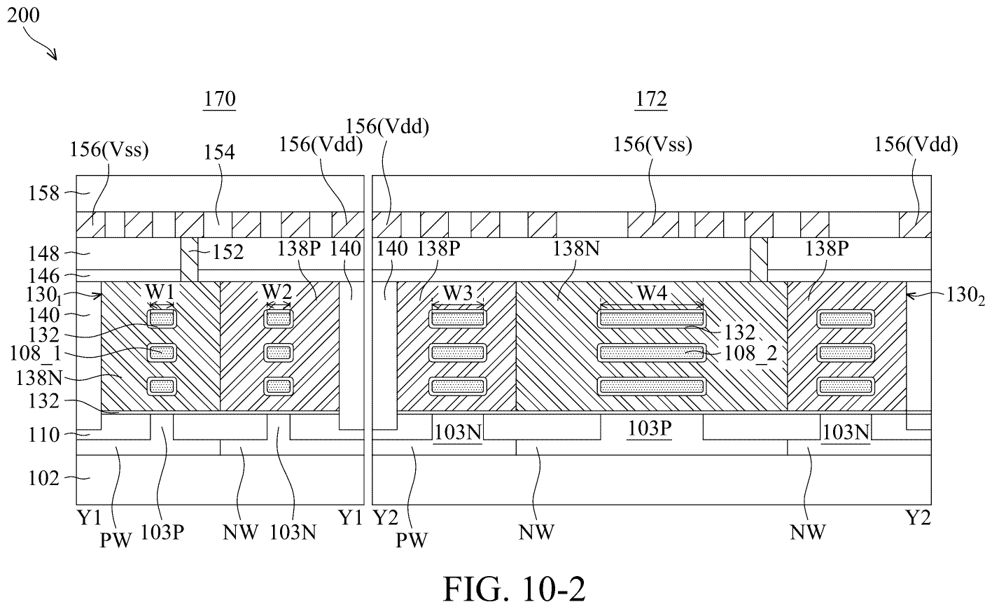

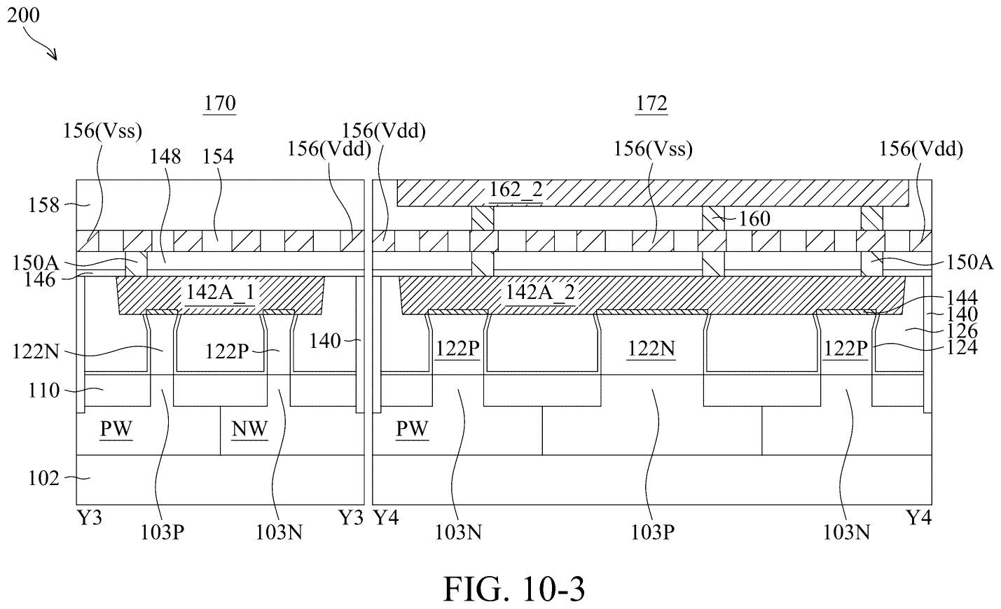

In the second cell region 172, the drain-node contact plug 142A_2 is electrically connected in parallel to the line 162_2 of the second-level metal layer M2 through three second-level vias 160, three lines 156 of the first-level metal layer M1 and three first-level vias 150A, as shown in FIG. 10-3, in accordance with some embodiments.

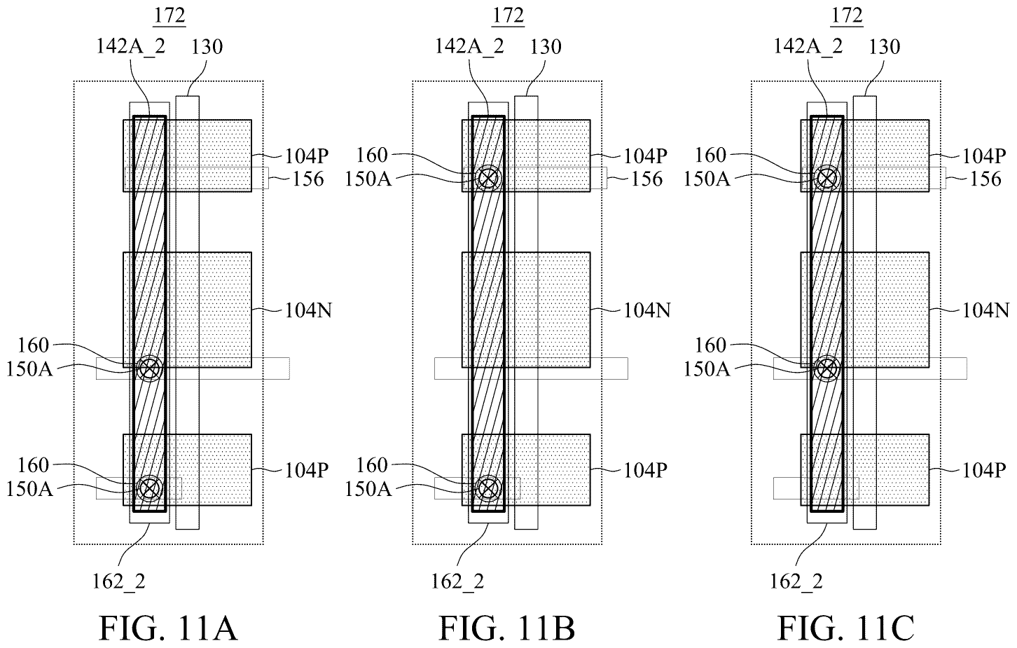

FIGS. 11A, 11B and 11C illustrate the various configurations between a drain-node contact plug 142A in a second cell region 172 of the cell array 50D and a line 162_2 of a second-level metal layer (M2), in accordance with some embodiments of the disclosure. The drain-node contact plug 142A_2 and the line 162_2 are electrically connected in parallel through two second-level vias 160, two lines 156 and two first-level vias 150A, as shown in FIGS. 11A, 11B and 11C, in accordance with some embodiments.

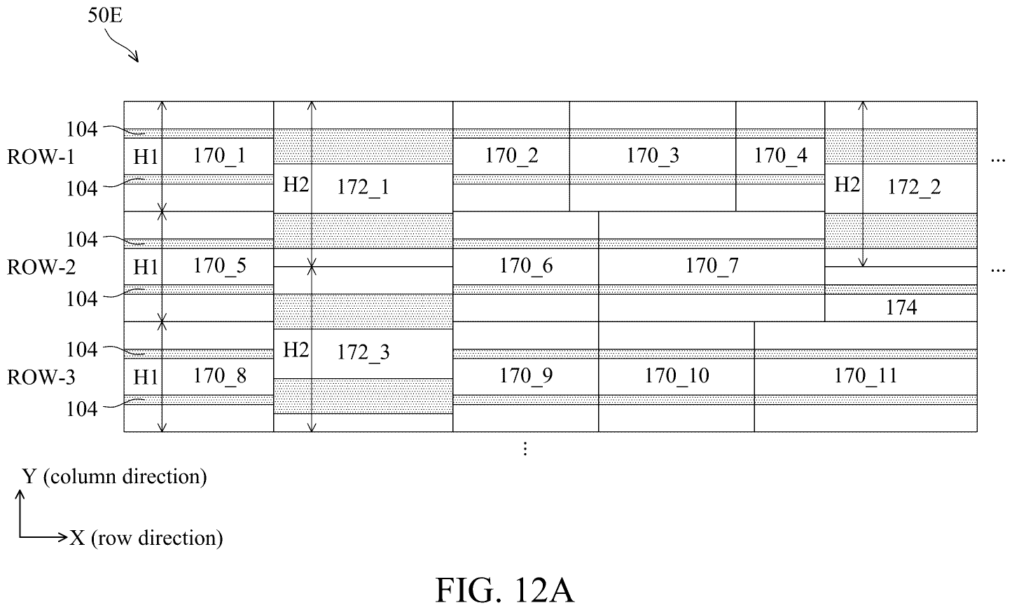

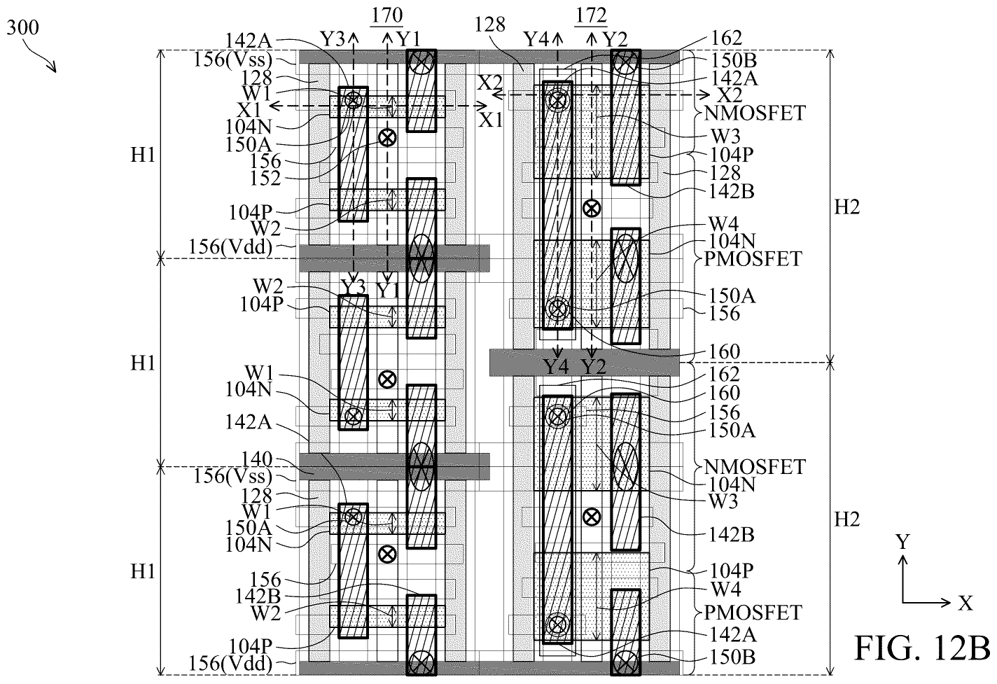

FIG. 12A is a top view of a standard cell array 50E, in accordance with some embodiments of the disclosure.

The standard cell array 50E includes a plurality of first cell regions 170 and a plurality of second cell regions 172 arranged in rows and in columns, as shown in FIG. 12A, in accordance with some embodiments. The first cell regions 170 include high-density circuits, and the second cell regions include high-current circuits, in accordance with some embodiments. The cell height H1 of the first cell region 170 is less than the cell height H2 of the second cell region 172, in accordance with some embodiments. In specific, the ratio of the cell height H2 to the cell height H1 is about 1.5. As a result, three first cell regions 170 are matched with two second cell regions 172 in the column direction, and thus the first cell regions 170 and the second cell regions 172 can be arranged in the same cell array, in accordance with some embodiments. In some embodiments, the high-current circuits in the cell region 50E may achieve a good balance between the high on-state current and high area utilization. Furthermore, the cell array 50E may also include a dummy cell region 174 where no function circuit is formed, in accordance with some embodiments.

FIG. 12B is a layout (top view) illustrating a semiconductor structure 300 including three first cell regions 170 and two second cell regions 172 in the standard cell array 50E of FIG. 12A, in accordance with some embodiments of the disclosure. The first cell regions 170 may be separate from the second cell regions 172, or alternatively abut and/or are immediately adjacent to the second cell regions 172.

In some embodiments, the channel width W3 of the active region 104N in the second cell region 172 is greater than the channel width W1 of the active region 104N in the first cell region 170. In some embodiments, the ratio (W3/W1) of the channel width W3 to the channel width W1 is in a range from about 2 to about 8. In some embodiments, the channel width W4 of the active region 104P in the second cell region 172 is greater than the channel width W2 of the active region 104P in the first cell region 170. In some embodiments, the ratio (W4/W2) of the channel width W4 to the channel width W2 is in a range from about 2 to about 8.

In some embodiments, the ratio (W3/W1) is equal to the ratio (W4/W2). In some other embodiments, the ratio (W3/W1) is not equal to the ratio (W4/W2). In some embodiments where the first cell regions 170 and the second cell region 172 are abutted, and at least two fin-cut structures 128 correspond to the boundary between the first cell regions 170 and the second cell region 172.

In the second cell region 172, one contact plug 142A is electrically connected to the drain nodes (or terminals) of both the n-channel nanostructure transistor NMOSFET the p-channel nanostructure transistor PMOSFET, in accordance with some embodiments. In the second cell region 172, two contact plugs 142B are electrically connected to the respective source nodes (or terminals) of the n-channel nanostructure transistor NMOSFET the p-channel nanostructure transistor PMOSFET, in accordance with some embodiments. In some embodiments, a Vdd power rail 156 passes through the interior of one of the second cell regions 172, and a Vss power rail 156 passes through the interior of the other second cell region 172.

In each of the second cell regions 172, the drain-node contact plug 142A is electrically connected in parallel to a line 162 of the second-level metal layer (M2) through two second-level vias 160, two lines 156 of the first-level metal layer (M1) and two first-level vias 150A, in accordance with some embodiments. Although not shown, the drain-node contact plug 142A in the first cell region 170 is electrically connected in series to a line 162 of the second-level metal layer (M2).

FIGS. 13-1, 13-2 and 13-3 are cross-sectional views of a semiconductor structure 300, in accordance with some embodiments of the disclosure. FIGS. 13-1, 13-2 and 13-3 illustrate the semiconductor structure 300 respectively corresponding to line X1-X1 and line X2-X2, line Y1-Y1 and line Y2-Y2, and line Y3-Y3 and line Y4-Y4 of FIG. 12B. The semiconductor structure 300 includes a first cell region 170 and a second cell region 172 which may be the cells 170 and 172 in the cell array 50E of FIG. 12A, in accordance with some embodiments. The formation of the semiconductor structure 300 may be similar to the formation of the semiconductor structure 100 described above in FIGS. 5A-1 to 5D-3, in accordance with some embodiments.

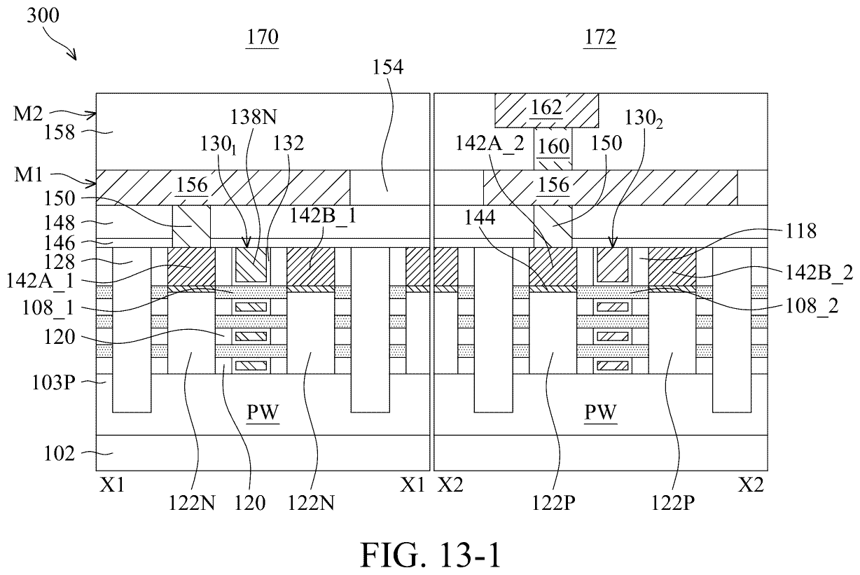

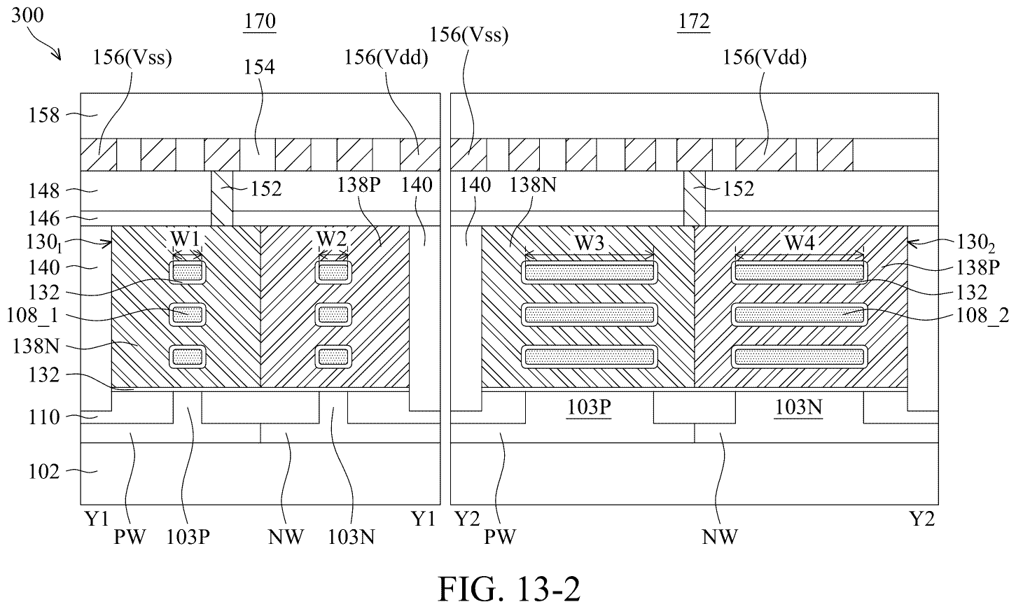

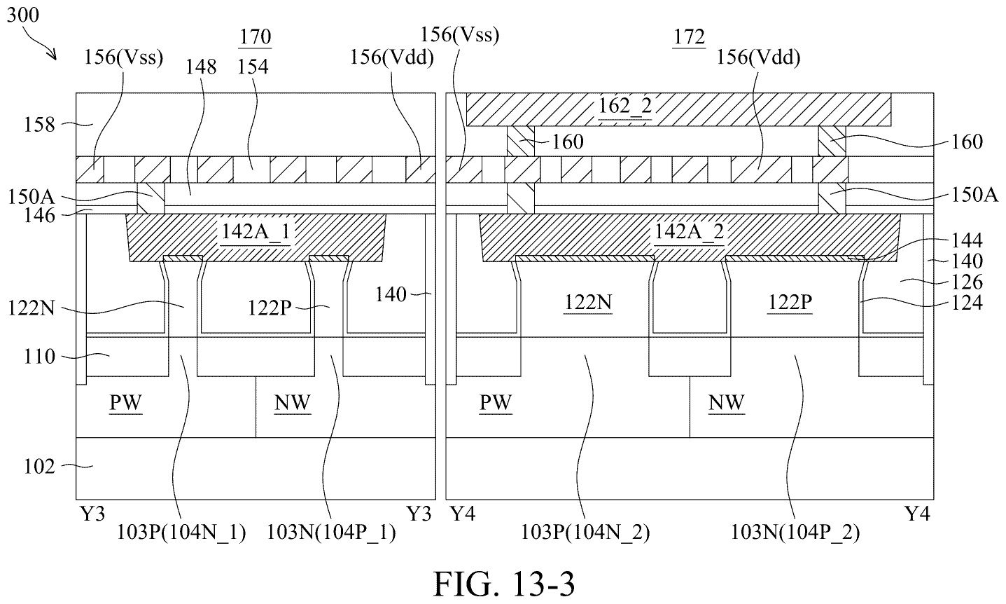

In the second cell region 172, the drain-node contact plug 142A_2 is electrically connected in parallel to the line 162_2 of the second-level metal layer M2 through three second-level vias 160, three lines 156 of the first-level metal layer M1 and three first-level vias 150A, as shown in FIG. 13-3, in accordance with some embodiments.

As described above, the semiconductor structure includes a high-density circuit in the first cell region 170 and a high-speed circuit in the second cell region 172. The channel widths W3 and W4 of the high-speed circuit may be greater than the channel widths W1 and W2 of the high-density circuit. The high-speed circuit includes a drain-node contact plug 142A that is electrically connected in parallel to a line 156 of the second-level metal layer M2, thereby reducing the IR voltage drop of the high-speed circuit. The high-density circuit includes a drain-node contact plug 142A that is electrically connected in series to a line 156 of the second-level metal layer M2, thereby increasing connection density. Therefore, more design freedom and co-optimization of component density and device performance of the resulting semiconductor device may be achieved.

Embodiments of a semiconductor structure may be provided. The semiconductor structure may include a circuit, a contact plug and a metal layer. The contact plug on the drain nodes of the n-type transistor and the p-type transistor of the circuit. A line of the metal layer and the contact plug are electrically connected in parallel. Therefore, the IR voltage drop may be reduced, which may boost the performance of the resulting semiconductor device.

In some embodiments, a semiconductor structure is provided. The semiconductor structure includes a first circuit in a first cell region, a first contact plug, a first metal layer and a second metal layer. The first circuit includes a first n-type nanostructure transistor and a first p-type nanostructure transistor. The first contact plug is electrically connected to the drain nodes of the first n-type nanostructure transistor and the first p-type nanostructure transistor. The first metal layer is over the first contact plug, and includes a first line and a second line electrically connected to the first contact plug. The second metal layer is over the first metal layer, and includes a third line electrically connected to both the first line and the second line.

In some embodiments, a semiconductor structure is provided. The semiconductor structure includes a first cell region and a second cell region. The first cell region includes a first transistor including a first channel layer, and a second transistor including a second channel layer. The first transistor and the second transistor share a first gate stack. The second cell region includes a third transistor including a third channel layer, a fourth transistor including a fourth channel layer. The third transistor and the fourth transistor share a second gate stack. In a horizontal direction that is parallel to a longitudinal direction of the first gate stack, a third channel layer is wider than the first channel layer and the fourth channel layer is wider than the second channel layer. The semiconductor structure also includes a first contact plug on drain nodes of the first transistor and the second transistor, a second contact plug on drain nodes of the third transistor and the fourth transistor. The semiconductor structure also includes a first metal layer over the first contact plug and the second contact plug, and a second metal layer over the first metal layer. A first line in the second metal layer and the second contact plug are electrically connected in parallel through at least two lines in the first metal layer.

In some embodiments, a semiconductor structure is provided. The semiconductor structure includes a first gate stack wrapping around a first plurality of nanostructures and a second plurality of nanostructures. The semiconductor structure also includes a first source/drain feature and a second source/drain feature adjoining the first plurality of nanostructures and the second plurality of nanostructures, respectively. The semiconductor structure also includes a first contact plug on both the first source/drain feature and the second source/drain feature, a first via and a second via on the first contact plug, and a first metal line and a second metal line on the first via and the second via, respectively. The semiconductor structure also includes a third via and a fourth via on the first metal line and the second metal line, respectively, and a third metal line on both the third via and the fourth via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first circuit in a first cell region, the first circuit comprising a first n-type nanostructure transistor and a first p-type nanostructure transistor;
a first contact plug electrically connected to drain nodes of the first n-type nanostructure transistor and the first p-type nanostructure transistor;
a first metal layer over the first contact plug and comprising a first line and a second line electrically connected to the first contact plug; and
a second metal layer over the first metal layer and comprising a third line electrically connected to both the first line and the second line.

2. The semiconductor structure as claimed in claim 1, wherein the third line at least partially overlaps the first contact plug.

3. The semiconductor structure as claimed in claim 1, further comprising:
a first via interposed between the first line and the first contact plug;
a second via interposed between the second line and the first contact plug;
a third via interposed between the first line and the third metal line, wherein the third via at least partially overlaps the first via; and
a fourth via interposed between the second line and the third metal line, wherein the fourth via at least partially overlaps the second via.

4. The semiconductor structure as claimed in claim 1, further comprising:
a second circuit in a second cell region, the second circuit comprising a second n-type nanostructure transistor and a second p-type nanostructure transistor; and
a second contact plug electrically connected to drain nodes of the second n-type nanostructure transistor and the second p-type nanostructure transistor; wherein:
the first n-type nanostructure transistor of the first circuit includes a first plurality of nanostructures having a first width in a horizontal direction that is parallel to a longitudinal axis of the first contact plug, and
the second n-type nanostructure transistor of the second circuit includes a second plurality of nanostructures having a second width in the horizontal direction, and the second width is less than the first width.

5. The semiconductor structure as claimed in claim 4, further comprising:
The second p-type nanostructure transistor of the first circuit includes a third plurality of nanostructures having a third width in the first horizontal direction, and
the second p-type nanostructure transistor of the second circuit includes a fourth plurality of nanostructures having a fourth width in the first horizontal direction, and the fourth width is less than the third width.

6. The semiconductor structure as claimed in claim 4, wherein a ratio of the first width to the second width is in a range from about 1.5 to about 8.

7. The semiconductor structure as claimed in claim 1, wherein the first metal layer further comprises:
a Vss power rail electrically connected to source nodes of the first n-type nanostructure transistor of the first circuit and the second n-type nanostructure transistor of the second circuit; and
a Vdd power rail electrically connected to source nodes of the first p-type nanostructure transistor of the first circuit and the second p-type nanostructure transistor of the second circuit.

8. The semiconductor structure as claimed in claim 1, wherein the first cell region abuts the second cell region, and the semiconductor structure further comprises:
a fin-cut structure on a boundary between the first cell region and the second cell region.

9. The semiconductor structure as claimed in claim 1, wherein the first metal layer further comprises a fourth line electrically connected to the first contact plug and the third line of the second metal layer.

10. A semiconductor structure, comprising:
a first cell region comprising a first transistor including a first channel layer, and a second transistor including a second channel layer, wherein the first transistor and the second transistor share a first gate stack;
a second cell region comprising a third transistor including a third channel layer, a fourth transistor including a fourth channel layer, wherein the third transistor and the fourth transistor share a second gate stack, in a horizontal direction that is parallel to a longitudinal direction of the first gate stack, a third channel layer is wider than the first channel layer and the fourth channel layer is wider than the second channel layer;
a first contact plug on drain nodes of the first transistor and the second transistor;
a second contact plug on drain nodes of the third transistor and the fourth transistor;
a first metal layer over the first contact plug and the second contact plug; and
a second metal layer over the first metal layer, wherein a first line in the second metal layer and the second contact plug are electrically connected in parallel through at least two lines in the first metal layer.

11. The semiconductor structure as claimed in claim 10, wherein a first cell height of the first cell region is equal to a second cell height of the second cell region.

12. The semiconductor structure as claimed in claim 10, wherein a first cell height of the first cell region is 1.5 times or twice a second cell height of the second cell region.

13. The semiconductor structure as claimed in claim 10, wherein a second line in the second metal layer is electrically connected in series to the first contact plug through a line in the first metal layer.

14. The semiconductor structure as claimed in claim 10, wherein the second gate stack is longer than the first gate stack in the horizontal direction.

15. The semiconductor structure as claimed in claim 10, wherein in a plan view, the second contact plug is confined within an area of the first line of the second metal layer.

16. A semiconductor structure, comprising:
a first gate stack wrapping around a first plurality of nanostructures and a second plurality of nanostructures;
a first source/drain feature and a second source/drain feature adjoining the first plurality of nanostructures and the second plurality of nanostructures, respectively;
a first contact plug on both the first source/drain feature and the second source/drain feature;
a first via and a second via on the first contact plug;
a first metal line and a second metal line on the first via and the second via, respectively;
a third via and a fourth via on the first metal line and the second metal line, respectively; and
a third metal line on both the third via and the fourth via.

17. The semiconductor structure as claimed in claim 16, further comprising:
a second gate stack wrapping around a third plurality of nanostructures and a fourth plurality of nanostructures, wherein in a horizontal direction that is parallel to a longitudinal direction of the first gate stack, a third plurality of nanostructures is narrower than the first third plurality of nanostructures and the fourth plurality of nanostructures is narrower than the second plurality of nanostructures;
a third source/drain feature and a fourth source/drain feature adjoining the third plurality of nanostructures and the fourth plurality of nanostructures, respectively; and
a second contact plug on both the third source/drain feature and the fourth source/drain feature, wherein in the horizontal direction, the second contact plug is shorter than the first contact plug.

18. The semiconductor structure as claimed in claim 17, wherein the first plurality of nanostructures and the third plurality of nanostructures are located in a p-type well, and the second plurality of nanostructures and the fourth plurality of nanostructures are located in an n-type well.

19. The semiconductor structure as claimed in claim 17, further comprising:
a first lower fin element continuously extending under the first plurality of nanostructures and the third plurality of nanostructures; and
a fin-cut structure interposed between the first gate stack and the second gate stack and extending into the lower fin element.

20. The semiconductor structure as claimed in claim 16, further comprising:
a first dielectric isolation structure below the first source/drain feature.
